(19) United States
(12) Patent Application Publication
(10) Pub. No.: US 2012/0159922 A1
(43) Pub. Date: Jun. 28, 2012

(54) TOP CYCLE POWER GENERATION WITH HIGH RADIANT AND EMISSIVITY EXHAUST

(76) Inventor: Michael Gurin, Glenview, IL (US)

(21) Appl. No.: 13/337,019

(22) Filed: Dec. 23, 2011

Related U.S. Application Data
(60) Provisional application No. 61/426,515, filed on Dec. 23, 2010.

(51) Int. Cl. F02C 6/00; H01L 31/00

(52) U.S. Cl. 60/39.15; 60/39.19; 136/253

(57) ABSTRACT

The present invention generally relates to power generation methods and secondary processes requiring high radiant and emissivity homogeneous combustion to maximize production output. In one embodiment, the present invention relates to a top cycle power generator with combustion exhaust modified to have radiant flux in excess of 500 kW per square meter and emissivity greater than 0.90, and supercritical CO2 power generating cycle to maximize exergy efficiency.

### FIELD OF THE INVENTION

The present invention generally relates to power generation having virtually all waste heat utilized within a secondary process requiring high radiant and emissivity. In all embodiments, the present invention utilizes a first top cycle power generation preferably either a thermophotovoltaic solid state device or ramjet.

### BACKGROUND OF THE INVENTION

Due to a variety of factors including, but not limited to, global warming issues, fossil fuel availability and environmental impacts, crude oil price and availability issues, alternative power generation methods must be developed to reduce carbon dioxide emissions. One such source of alternative power generation is a top cycle that exhausts thermal energy at levels suitable for at least one secondary process that is more effective when the top cycle exhaust is transformed to a highly radiant energy source preferably with high emissivity to maximize heat transfer. One such way to transform exhaust from combustion is to use flameless combustion by leveraging the enthalpy of exhaust to preheat an oxidant source and preferably a fuel source (e.g., fuel is natural gas, syngas, or volatilized organic chemicals from coal) individually to above the fuels autoignition temperature. The further use of soot increases the emissivity to maximize radiant heat transfer into a secondary process. Energy conversion into electricity is optimized by maximizing high side temperature, whether it be for a thermodynamic cycle where Carnot efficiency is increased or for solid state conversion where an “artificial” sun enables the use of thermophotovoltaic devices.

Traditional top cycle power generators utilize combustion processes that limit the exhaust conditions to less than 1500 degrees Fahrenheit and often less than 1000 degrees Fahrenheit. This limits the secondary processes to low efficiency as a result of relatively low quality (i.e., low exergy), which include organic Rankine cycles, steam cycles, and supercritical CO2 cycles. Most high temperature furnaces, including power generator boilers (i.e., coal or biomass) require high radiant energy transfer in order to not limit production rates. As noted, the exhaust from the top cycle has relatively low exergy and particularly low emissivity often limited by the exhaust gas emissivity which is less than 0.1.

A high temperature top cycle, one in which exhaust temperatures exceed 1500 degrees Fahrenheit, where exhaust is transformed into a high radiant and emissivity to transfer energy into a secondary process, maximizes exergy efficiency and not simply enthalpy efficiency.

The combined limitations of each individual component being the top cycle power generator, fuel and/or oxidant inputs to transform top cycle exhaust into high radiant and emissivity for a secondary process presents significant challenges that are further elaborated when seeking to maximize system efficiency while reducing exhaust emissions.

### SUMMARY OF THE INVENTION

The present invention preferred embodiment relates to ultra-high temperature power production process has a high temperature exhaust that is subsequently utilized with a downstream process that preferentially operates with high radiant and emissivity homogeneous flameless combustion. Most of the preferred embodiments further include a supercritical CO2 thermodynamic power generating cycle to utilize enthalpy from the stoichiometric release of combustion exhaust from the combined ultra-high temperature power production process and the downstream process.

### BRIEF DESCRIPTION OF THE DRAWINGS

FIG. 1 is a sequential flow diagram of one embodiment of an integrated top cycle power generator with a secondary furnace operating preferably with either a ramjet or thermophotovoltaic device in accordance with the present invention;

FIG. 2 is a sequential flow diagram of one embodiment of an integrated top cycle power generator with a secondary furnace operating preferably where exhaust waste heat from the secondary furnace is utilized to preheat combustion air of the top cycle in accordance with the present invention;

FIG. 3 is a sequential flow diagram of one embodiment of an integrated top cycle power generator preferably operating as a 2 stage expander, where the exhaust heat from the top cycle is partially utilized to drive a Rankine cycle utilizing CO2 as a working fluid to maximize exergy efficiency;

FIG. 4 is a sequential flow diagram of one embodiment of an integrated top cycle power generator preferably operating as a 2 stage expander, where the exhaust heat from the top cycle is partially utilized to drive a Brayton cycle utilizing CO2 as a working fluid to maximize exergy efficiency;

FIG. 5 is a sequential flow diagram of one embodiment of an integrated top cycle power generator operating with a high radiant downstream furnace;

FIG. 6 is a sequential flow diagram of another embodiment of an integrated top cycle power generator operating with a high radiant downstream furnace;

FIG. 7 is a sequential flow diagram of one embodiment of an integrated top cycle power generator, with preheat by waste heat recovery of the bottom cycle, preferably operating as a 2 stage expander, where the exhaust heat from the top cycle is partially utilized to drive a Rankine bottom cycle utilizing CO2 as a working fluid to maximize exergy efficiency;

FIG. 8 is a sequential flow diagram of one embodiment of an integrated top cycle power generator operating with a high radiant downstream furnace and a simulated moving bed waste heat recovery system to preheat combustion air for the furnace;

FIG. 9 is a sequential flow diagram of one embodiment of an integrated top cycle power generator operating with a high radiant oxyfuel downstream furnace and a simulated moving bed waste heat recovery system to preheat combustion oxygen for the furnace;

FIG. 10 is a sequential flow diagram of a high radiant furnace with a simulated moving bed for waste heat recovery operating in a hybrid oxyfuel configuration;

FIG. 11 is a sequential flow diagram of a high radiant furnace with a first and a second simulated moving bed for waste heat recovery operating in a hybrid oxyfuel configuration;

FIG. 12 is a sequential flow diagram of a high radiant furnace with a first simulated moving bed for waste heat recovery operating in a hybrid oxyfuel configuration and a second simulated moving bed having exothermic carbonation;

FIG. 13 is a sequential flow diagram of a high radiant furnace with a first waste heat recovery heat exchanger to a bottom cycle Rankine power generator and a second waste heat recovery to transfer thermal energy from the Rankine power generator cycle to preheat the combustion air of the high radiant furnace;

FIG. 14 is a sequential flow diagram of top cycle power generator with a simulated moving bed for waste heat recovery to preheat combustion air for a boiler having exhaust that passes through a second simulated moving bed with exothermic media from carbonation to transfer thermal energy as preheat for the top cycle power generator;

FIG. 15 is another embodiment of a sequential flow diagram of top cycle power generator with a simulated moving bed for waste heat recovery to preheat combustion air for a boiler having exhaust that passes through a second simulated moving bed with exothermic media from carbonation to transfer thermal energy as preheat for the top cycle power generator;

FIG. 16 is another embodiment of a sequential flow diagram of top cycle power generator with a simulated moving bed as a first stage waste heat recovery operable as a recuperator for the top cycle a second stage waste heat recovery heat exchanger to transfer thermal energy to a Rankine or Brayton bottom cycle power generator;

FIG. 17 is another embodiment of a sequential flow diagram of top cycle power generator with a waste heat recovery heat exchanger operable as a bottom cycle evaporator and a second stage waste heat recovery simulated moving bed operable as a recuperator for the top cycle power generator;

FIG. 18 is an embodiment of a sequential flow diagram of top cycle power generator with a first waste heat recovery heat exchanger operable as a bottom cycle evaporator and a second stage waste heat recovery operable to transfer thermal energy to a wide range of processes or cycles, such that the top cycle is an oxyfuel cycle to minimize the size of the first waste heat recovery heat exchanger by at least 60% and as much as 85% as compared to a heat recovery steam generator;

FIG. 19 is a further embodiment of a sequential flow diagram of top cycle power generator as depicted in FIG. 18 with the additional preheating and dilution of fuel for top cycle, preferably at supercritical pressures, using a supercritical CO2 bottom cycle and a CO2 sequestration system as an on-demand CO2 source;

FIG. 20 is another embodiment of a sequential flow diagram of top cycle power generator as depicted in FIG. 19 with the additional preheating and dilution of fuel for top cycle using waste heat of the bottom cycle;

FIG. 21 is a sequential flow diagram of a prior art configuration for a typical coal fire power plant;

FIG. 22 is a sequential flow diagram of an embodiment for a coal fire power plant having a Brayton or Rankine CO2 power generating cycle with the economize thermal energy source from the bottom cycle of the CO2 power generating cycle;

FIG. 23 is a sequential flow diagram of an embodiment for a Rankine or Brayton power generating cycle driven by waste heat from a first thermal source and a regenerative oxidizer to boost the operating temperature;

FIG. 24 is a sequential flow diagram of an embodiment for a Rankine or Brayton power generating cycle driven by waste heat from a first thermal source and a concentrated solar source to boost the operating temperature;

FIG. 25 is a sequential flow diagram of an embodiment for a Rankine or Brayton power generating cycle driven by combustor with an integral simulated moving bed as a first thermal source and a concentrated solar source to boost the operating temperature;

FIG. 26 is a sequential flow diagram of an embodiment similar to FIG. 25 with the further addition of a thermophotovoltaic power generator as a top cycle to the Rankine or Brayton power generating cycle.

### DETAILED DESCRIPTION OF THE INVENTION

The term “in thermal continuity” or “thermal communication”, as used herein, includes the direct connection between the heat source and the heat sink whether or not a thermal interface material is used.

The term “fluid inlet” or “fluid inlet header”, as used herein, includes the portion of a heat exchanger where the fluid flows into the heat exchanger.

The term “fluid discharge”, as used herein, includes the portion of a heat exchanger where the fluid exits the heat exchanger.

The term “expandable fluid”, as used herein, includes the all fluids that have a decreasing density at increasing temperature at a specific pressure of at least a 0.1% decrease in density per degree C.

The term “working fluid” is a liquid medium utilized to convey thermal energy from one location to another. The terms heat transfer fluid, working fluid, and expandable fluid are used interchangeably.

The term “concentrated solar receiver” is a device receiving solar flux as directed through reflection or optical transmission such that the solar irradiation is greater than 3 kilowatt per square meter.

The term “thermophotovoltaic cell” is a solid state device, one that directly converts photons to electrons, where a radiated spectrum of light ranging from ultraviolet through infrared produces direct current electricity. It is understood that a thermionic and a thermoelectric device are within the scope of alternative solid state devices.

The term “supercritical” is defined as a state point (i.e., pressure and temperature) in which a working fluid is above its critical point. It is understood within the context of this invention that the working fluid is supercritical at least on the high side pressure of a thermodynamic cycle, and not necessarily on the low side of the thermodynamic cycle.

The term “stoichiometric excess” is an amount of at least one chemical reactant that is greater than the quantity of reactants within a balanced chemical reaction.

The term “ramjet” is a rotary device that eliminates the need for a conventional bladed compressor (when a ramjet compressor) and turbine (when a ramjet expander) as used in traditional gas turbine engines. One embodiment of a ramjet is an inside-out supersonic circumferential rotor having integrated varying-area shaped channels in its radially inward surface, in which compression, combustion and expansion occur. The “inside-out” design places all rotating parts under compressive centrifugal loading.

The term “top cycle” is a power conversion cycle at the highest exergy state (i.e., having the maximum ability to produce useful work, also synonymous with topping cycle.

The term “oxidant source” is an air composition that contains oxygen ranging from 1 percent on a mass fraction basis to a highly enriched air composition up to 100 percent on a mass fraction basis, including the highly energetic monoatomic oxygen.

The term “fuel” is a chemical reactant that is exothermic during an oxidation reaction.

The term “CO2 capture system” is a method of effectively isolating carbon dioxide from an air composition, such as combustion exhaust, by any method ranging from carbonation chemical reaction, adsorption, or absorption. The process of isolating carbon dioxide is reversible such that an increase of temperature beyond a critical point changes the equilibrium point.

The term “recuperator” is a method of recovering waste heat downstream of an expander and transferring the thermal energy upstream of either a compressor, turbocompressor or pump.

The term “simulated moving bed” is as known in the art of adsorption, but modified to emulate a counter-flow heat exchanger such the a series of beds consisting of solid yet porous media relatively isolated by insulation and at least two series of beds such that one bed is storing thermal energy (e.g., example in a left to right direction in terms of the series of beds) while the other bed is discharging thermal energy e.g., example in a right to left direction in terms of the series of beds)

The term “exhaust port” is any method capable of discharging a working fluid that can include safety valve, pressure regulated valve, expansion device venting to atmosphere, etc.

The present invention generally relates to a top cycle power generation system having both an ultrahigh temperature (typical discharge temperatures above 2000 degrees Fahrenheit) and a secondary process requiring thermal energy from a highly radiative and emissive source. Additional embodiments include a bottom cycle either utilizing an integral working fluid (typically CO2) management system with CO2 sequestration/capture system that enables the system to increase or decrease the mass of the working fluid within the circulation loop of a second closed loop system thermodynamic power generation cycle.

Here, as well as elsewhere in the specification and claims, individual numerical values and/or individual range limits can be combined to form non-disclosed ranges.

The heat transfer fluid within the embodiments is preferably a supercritical fluid as a means to reduce the pressure drop within the heat exchanger. The supercritical fluid is effectively limited to gases (CO2, H2O, He2). The specifically preferred supercritical fluid is CO2.

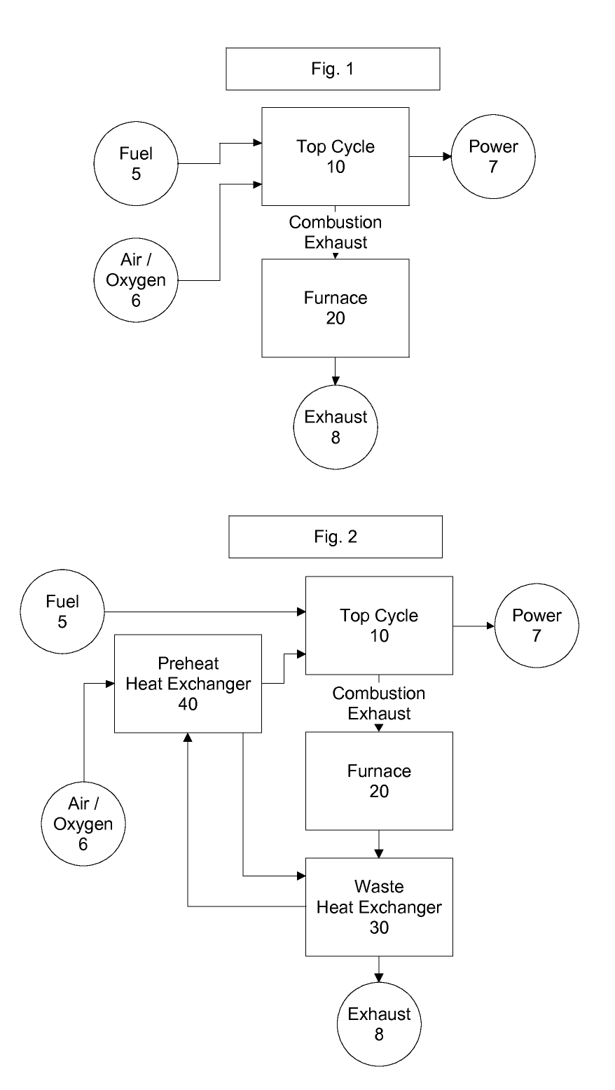

Exemplary embodiments of the present invention will now be discussed with reference to the attached Figures. Such embodiments are merely exemplary in nature. Furthermore, it is understand as known in the art that sensors to measure thermophysical properties including temperature and pressure are placed throughout the embodiments as known in the art, most notably positioned to measure at least one thermophysical parameter for at least one thermodynamic state point. The utilization of valves as standard mass flow regulators is assumed (i.e., not depicted) to be as known in the art and can also include variable flow devices, expansion valve, turboexpander, two way or three way valves. The utilization of methods to remove heat from the working fluid by a condensor (used interchangeably with condenser) is merely exemplary in nature as a thermal sink and can be substituted by any device having a temperature lower than the working fluid temperature including absorption heat pump desorber/generator, liquid desiccant dehumidifier, process boilers, process superheater, and domestic hot water. With regard to FIGS. 1 through 26, like reference numerals refer to like parts.

The function of the top cycle power generation system is to serve as a means of maximizing exergy efficiency concurrently with enthalpy efficiency by operating at a discharge temperature from the top cycle sufficiently high to utilize the waste heat from the top cycle in bottom cycles, furnaces, or solar concentrators where highly radiative and emissive conditions maximize heat transfer rate and minimize equipment size resulting in significantly reduced capital cost. Hereinafter, the term “adding fluid” is increasing the mass of expandable fluid by at least 0.5% on a weight basis. Hereinafter, the term “removing fluid” is decreasing the mass of expandable fluid by at least 0.5% on a weight basis. It is understood that adding or removing fluid from a thermodynamic power generating cycle can take place at either the high pressure side (i.e., downstream of the pump/turbocompressor) or low pressure side (upstream of the expander) though preferentially occurs on the low pressure side.

One embodiment of the invention, which is an energy production system that maximizes exergy efficiency and simply enthalpy efficiency, is the combination of thermodynamic power generating top cycle consisting of a first thermodynamic power generating cycle with a combustor (first combustion stage) and a first working fluid (air, enriched or pure oxygen, or supercritical CO2 with co-injected oxidant and fuel) that producing combustion exhaust (first stage exhaust) that is waste heat as a byproduct of the power generation process. The preferred embodiment is an exhaust temperature from the first thermodynamic power generating cycle within 100 degrees Celsius (or specifically preferred within 20 degrees Celsius) of the discharge temperature from a second combustion stage (boiler, furnace, kiln, reactor) consuming the first combustion stage exhaust. Additional oxidant is injected downstream of the first thermodynamic power generating cycle “TPG” exhaust, such that the enthalpy from the first TPG waste heat is utilized to preheat the oxidant preferably to above the autoignition temperature of the fuel, and more preferably at least 5 degrees Celsius above the fuel's autoignition temperature. The first TPG waste heat is preferably to have a temperature greater than 1000 degrees Celsius, and in virtually all cases will have an emissivity less than 0.50. In the preferred embodiment, a stoichiometric excess of fuel (preferably between 0.1 percent to 10 percent relative to oxidant, and specifically preferred between 0.1 percent to 1 percent) is added to the first TPG combustor such that soot or soot precursors are created preferably at a level between 5 ppm to 1000 ppm (created by the incomplete combustion of the fuel, though specifically preferred between 5 ppm and 100 ppm). In the specifically preferred embodiment, the first TPG combustion exhaust is split at the stoichiometric ratio between oxidant and fuel for the second stage combustion upstream of the second stage combustor such that the additional oxidant and/or fuel required to satisfy the second combustion stage process throughput and exit state point are achieved and that both the additional oxidant and/or fuel are both preheated and diluted with the first TPG combustion exhaust. Alternatively, the additional oxidant can be at least in part preheated by the second stage of combustion exhaust. Yet another alternative is additional fuel at a stochiometric excess of any uncombusted oxidant is injected into the first combustion stage exhaust, and then additional preheated oxidant is injected at a temperature above the fuel's autoignition temperature. The preferred composition of the oxidant is at least 30 percent oxygen on a mass fraction basis. The additional oxidant can be injected at various injection points with respect to the second stage combustion in order to maximize the capture of enthalpy from either the first TPG or second stage combustion exhaust. The injection points can be downstream of the first TPG, downstream of the second combustion stage combustion exhaust discharge, or downstream of yet another thermodynamic power generating cycle as a bottom cycle to that TPG cycle. The same injection points can be utilized to preheat the fuel, or diluted fuel relative to the second combustion stage. The second stage of combustion exhaust includes a wide range of processes preferably combusted within an industrial furnace including furnaces of steel, aluminum, silicon, and glass; or more preferably within an industrial kiln including ceramic, and cement.

The now preheated and diluted oxidant and fuel are injected into the second stage combustor, with the soot or soot precursors created to achieve a radiant flux of greater than 100 kW per square meter (preferably greater than 200 kW, and specifically preferred to be greater than 500 kW) and emissivity greater than 0.2 (preferably greater than 0.50, and specifically preferred to be greater than 0.80, and particularly preferred to be greater than 0.90). These conditions enable the highest throughput when heat transfer is realized through radiated energy rather than convection, by increasing the emissivity within the second combustion stage by at least 10 percent (preferably by at least 50 percent and specifically preferred by at least 100 percent) relative to the emissivity of the combustion exhaust from the first TPG. It is understood that any virtually any combination of higher radiant flux and emissivity is achieved by this invention, such as a radiant flux greater than 300 kW per square meter and emissivity greater than 0.5, radiant flux greater than 500 kW per square meter and emissivity greater than 0.8, or specifically preferred radiant flux greater than 500 kW per square meter and emissivity greater than 0.9.

All prior art, in which a combustion process (particularly for power generation) has temperatures and emissivity insufficient to radiate energy thus heat transfer is limited to convection through a rotary heat wheel (or the like), an air-to air, or an air-to-liquid heat exchanger. The present invention does not require any heat exchangers to be present in order to utilize the first TPG waste heat for the second stage combustor. Another advantage of this embodiment is such that the stoichiometric excess of fuel within the first TPG combustor will chemically reduce a portion of the NOx produced. Furthermore, the subsequent addition of fuel within the second stage combustor will also chemically reduce a portion of the NOx produced within the first TPG, while the typically lower combustion temperature of the second stage as compared to the first TPG also reduces final NOx levels.

Another embodiment of the invention, is the first TPG utilizing a ramjet. The preferred embodiment is an inside-out ramjet that sustains the combustor exhaust temperatures well in excess of 1000 degrees Celsius. Yet another embodiment is such that the three main “stages” within the ramjet, operational within a Brayton cycle, is the physical separation of each stage such that an inside-out ramjet compressor is separated from the combustion stage (i.e., ramjet combustor), and also separated from the inside-out ramjet expander. This configuration enables the first TPG to take advantage of recuperation to reduce fuel consumption, with the preferred configuration utilizing waste heat from either the first TPG or the second combustion stages. Yet another advantage of the invention, is that the TPG operates at a pressure typically lower than the supercritical pressure of carbon dioxide “CO2” or water (i.e., water vapor, steam, etc.), which is vital for operation at temperatures in excess of 1000 degrees Celsius (or preferably in excess of 1500 degrees Celsius).

Yet another embodiment of the invention is a combined TPG top cycle having a first TPG cycle having a first expander device and a first combustion stage and a first working fluid. The first TPG discharges combustion exhaust preferably at a pressure greater than 100 psi (it is understood that any pressure at least 2 psia is within scope of operation) than ambient pressure. The combustion exhaust consists predominantly of carbon dioxide and water vapor. The first TPG cycle operates as a top cycle to a second TPG cycle with a second working fluid (different than the first TPG, and preferably relatively pure CO2 i.e., above 90 percent mass fraction). The second TPG is a supercritical cycle such that upstream of the second TPG's expander device there is an inlet pressure greater than the second working fluid supercritical pressure. The operation of such combination is critical to having the highest temperature components operational at relatively lower pressures. It is understood however, that the first TPG can also be a supercritical cycle such that pressure upstream of the first TPG expander is above the supercritical pressure of either nitrogen or oxygen (respectively dependent if the combustion is with natural air composition or an oxyfuel process). The waste heat is recovered from the first TPG and transferred to the second TPG through a heat transfer device. The heat transfer device can be a standard counter-flow heat exchanger as known in the art, or preferably a simulated moving bed suitable for the high temperatures of the first TPG combustion exhaust. The simulated moving bed can buffer the temperatures of the first TPG exhaust to ensure operation of the second TPG cycle evaporator continuously at temperatures less than 50 degrees Celsius below the critical strength vs temperature curve for the supercritical pressures of the second TPG. The exhaust of the first TPG downstream of the second TPG evaporator is then directed to a third expander device to produce additional mechanical or electrical energy. The preferred state point inlet pressure and inlet temperature are such that the water vapor from the first waste heat byproduct is condensed and phase separated upstream of the third expander. One advantage of this configuration is such that the second TPG evaporator does not experience the non-linearity of the heat transfer due to the steam to water phase change. Another advantage of this configuration is such that the second TPG evaporator will not experience severe corrosion due to the potentially high NOx levels produced at the high temperatures within the first TPG cycle or the condensing of steam vapor. The third expander for a third TPG cycle (or downstream of another TPG cycle) can be located downstream of combustion exhaust from the first TPG cycle or second TPG cycle, or as a bottom cycle of the first or second TPG cycle.

However, in another embodiment, the energy production system is integrated into existing boilers, specifically coal fired boilers, such that a retrofit enables coal fired boilers to operate at higher energy efficiency with reduced CO2 emissions where a CO2 TPG cycle is a first TPG cycle, and the balance of the existing coal fired boiler and power plant is the second TPG cycle (i.e., a steam cycle) having at least two of the three high pressure, intermediate pressure and low pressure expanders remaining in operation despite the economizer now having its thermal source at least in part from waste heat recovered and downstream of the first TPG cycle expander.

The preferred embodiment of the second TPG expander is a ramjet expander, and more specifically preferred to be an inside-out expander such that the expander is preferentially manufactured with ceramics that are solely experiencing compressive loads, a critical feature of a TPG cycle that is already operating at pressures above the supercritical pressure of CO2. Yet another preferred embodiment of the second TPG cycle is such that is consisting of multiple cascading cycles and that the first of the second TPG cascaded cycles is operating as a Brayton cycle (preferably with a working fluid of supercritical CO2) has an inside-out ramjet compressor due to the relatively high temperatures attributed to the discharge temperature from the first TPG cycle. The second of the second TPG cascaded cycles is operating as a Rankine cycle. Additional stages of the cascaded cycles are preferably operated as Rankine cycles, with it being understood that the working fluid for each of the cycles beyond the first of the cascaded cycles can be CO2, ammonia, water, or an organic chemical as known in the art. It is understood throughout the invention that a cascaded cycle void of a recuperator enables more waste heat to be effectively utilized.

A preferred embodiment for the first TPG top cycle consists of a sequential set of components in order of a top cycle compressor, a top cycle external preheat, a top cycle combustor, and a top cycle expander wherein the top cycle external preheat captures waste heat from the second stage of combustion exhaust.

Yet another embodiment of the above first TPG cycle is where the first combustion stage occurs at a pressure at least 5 psi greater than the supercritical pressure of carbon dioxide and a temperature at least 2 degrees Celsius greater than the supercritical temperature of carbon dioxide. The first TPG cycle having a working fluid predominantly of supercritical CO2 has the following advantages: a) dilute fuel with ability to preheat above autoignition temperature of the fuel, b) reduced physical size of the expander to reduce windage losses and diameter of the entire pressure vessel, c) a preheated oxidant such that within the combustor the fuel and oxidant experience homogeneous and flameless combustion bypassing the industry experience of flame instability within traditional (i.e., non inside-out) ramjets. As in other embodiments, it is understood that the fuel and/or oxidant can be preheated either or both of first stage of combustion exhaust or second stage thermodynamic power generating cycle downstream of the second expander device.

Yet another embodiment addresses the industry recognized problem of working fluid leakage, which is a particular issue for supercritical cycles and most specifically of note for supercritical CO2. Anything that can be done to diminish, if not eliminate, the requirement to purchase CO2 to replace the leaked CO2 is essential for profitable operation of the energy production system. The combination of the first TPG cycle, preferably as a supercritical cycle itself, produces CO2 as a significant component within the first TPG cycle combustion exhaust. The further step of capturing the CO2, as known in the art, within a process that is reversible enables a high purity stream of CO2 to be discharged from the CO2 capture system. A preferred embodiment of the CO2 capture system is an exothermic carbonation reaction where the thermal energy created by the reaction can be utilized for a first, second, or third TPG cycle. Furthermore, the exothermic carbonation reaction is reversible and using waste heat from any point of the first, second, or third TPG cycle can be used to drive the CO2 by disassociation of carbonate. The now released CO2 is incorporated into the second TPG cycle in a controlled manner to displace the CO2 leaked over time by operation of the second TPG cycle (particularly the moving parts of pump/compressor and expander) by boosting the pressure of the CO2 to within 5 psi of the second TPG cycle upstream of the second TPG cycle pump/compressor. When the first TPG is operated as a supercritical cycle having an expander discharge pressure above the low side pressure of the second TPG cycle, the CO2 is captured downstream of the condensing of water vapor from the first TPC cycle first stage exhaust at a pressure at least 5 psi greater than the low side pressure of the second TPG cycle. The issue of CO2 mass flow leakage is a particularly important issue for smaller scale systems (e.g., kW ratings of less than 2000 kW, and specifically less than 250 kW). Typical methods to reduce leakage include dry seals or hermetically sealing, though at particularly significant capital expense relative to system cost for smaller scale systems. The ability to utilize CO2 captured from the combustion gases enable the requirement of dry seal or hermetic seal to be eliminated. The ability to capture CO2 from combustion exhaust is best achieved with minimal parasitic energy losses when the pressure downstream of the first TPG cycle is greater than 100 psi, preferred greater than 500 psi, more preferred greater than 1000 psi, and specifically preferred greater than 1500 psi. A corresponding temperature greater than 500 degrees Celsius is preferred, more preferred is greater than 700 degrees Celsius, particularly preferred is greater than 1000 degrees Celsius, specifically preferred is greater than 1200 degrees Celsius, and uniquely preferred is greater than 1500 degrees Celsius (when used with inside-out ramjet expander).

It is understood that virtually every embodiment of this invention can further include a solar concentrator receiver. A thermal input of a solar concentrator receiver, particularly a receiver having a temperature above the upstream temperature of the second TPG cycle pump/compressor, more preferable above the upstream temperature of the first TPG cycle compressor, specifically preferable above the temperature of either downstream of the second combustor or first TPG combustor has the distinct advantage of not creating any combustion byproducts. The lack of combustion byproducts enables up to 100 percent of the working fluid to be recirculated or recuperated. The solar flux as focused on the solar concentrator receiver has high energy wavelengths that are thermodynamically capable of heating the working fluid in excess of 4000 Kelvin. The solar concentrator receiver can be located anywhere within any of the TPG cycles, upstream or downstream of any of the combustors, but is preferably downstream of a combustor and upstream of an expander. The more preferable embodiment, preferred when the concentration ratio is above 100 and more preferred above 300 and particularly preferred above 1000 suns is such that the solar concentrator review is placed at the position to obtain the highest temperature throughout any of the TPG cycles. This placement limits the creation of NOx often associated with very high temperature combustion. One such embodiment is within the first TPG top cycle where the external preheat captures waste heat first from the second stage of combustion exhaust and then subsequently from a concentrated solar light source.

Another embodiment for a supercritical TPG cycle, whether it be a first TPG top cycle, or a second TPG bottom cycle is the combination of a waste heat recovery first evaporator and a second evaporator being the solar concentrated receiver. A particularly preferred embodiment further includes a simulated moving bed as a waste heat recovery device that provides unique advantages including buffering working fluid temperatures (particularly when the temperature exceeds 650 degrees Celsius or specifically exceeds 1000 degrees Celsius).

Yet another embodiment is the combination of a first evaporator being the solar concentrated receiver and an external combustor as a method to increase the thermodynamic efficiency of the TPG cycle (and preferably enabling the solar concentrated receiver to have a topping combustor to increase working fluid temperature at least 100 degrees Celsius higher than the maximum temperature within the solar concentrated receiver, and more importantly to enable the TPG cycle operate on demand and/or always at peak operating efficiency regardless of solar flux levels) including a simulated moving bed. A fundamental challenge with the prior art within solar concentrating receivers is the significant waste heat loss of an external or internal combustion process beyond the solar concentrating receiver temperature. The simulated moving bed, particularly when configured to recover waste heat from the combustion process and more importantly used to preheat at least one of the combustion process fuel or oxidant (the oxidant preferably has an oxygen mass fraction of greater than 40 percent up to 100 percent) sources. One preferred configuration is such that the simulated moving bed is downstream of the first TPG cycle expander. Yet another configuration is where the simulated moving bed is downstream of the second combustion stage. Another preferred configuration is a second TPG cycle that is void of a combustor such that the waste heat not recovered by the simulated moving bed evaporates supercritical CO2 within the second TPG cycle. A particularly preferred simulated moving bed consists of a chemical medium that has an exothermic carbonation reaction with reactant including CO2 from the combustion exhaust.

Another embodiment of a concentrated solar receiver is with an existing combustion fueled energy source that creates waste heat. The prior art has the fundamental disadvantage that supplementing waste heat with a supplemental combustor itself creates waste heat having comparable temperatures of the first waste heat source, thus having minimal impact on total efficiency. A second thermal source from a concentrated solar receiver is preferred to have a temperature at least 200 degrees Celsius greater than the first thermal source (i.e., waste heat). The preferred configuration is such that a supercritical CO2 working fluid from a TPG cycle is heated first by the first thermal source and then by the second thermal source to create through an expander mechanical or electrical power. The particularly preferred configuration uses waste heat from the TPG cycle to preheat the oxidant that has created the waste heat in the first place, thus having a secondary benefit of reduced energy consumption and reduced exhaust mass flow yielding a lower levelized cost of energy associated with the system that integrates the concentrated solar receiver. A control system monitors the CO2 working fluid maximum operating temperature, and controls a fuel mass flow regulator, such that the CO2 working fluid temperature downstream of the first thermal source limits the CO2 working fluid temperature discharge temperature discharged from the concentrated solar receiver and upstream of the expander to be less than the CO2 maximum operating temperature.

Another preferred embodiment integrates a thermophotovoltaic cell that consists of a multijunction (i.e., dual, triple, or quadruple) photovoltaic cells having an average quantum energy conversion efficiency of greater than 80 percent for the multijunction photovoltaic cell operable spectrum range. The thermophotovoltaic cell is a solid state energy conversion device that captures at least 5 percent of the radiant energy from within any of the combustors (i.e., first or second TPG, boiler, etc.). The thermophotovoltaic cell is preferably on the interior facing portion of the combustor or boiler, such as the boiler or furnace wall. And in virtually all cases the thermophotovoltaic cell will be on a substrate containing a heat exchanger, preferably a heat exchanger that provides thermal energy to any of the first, second, or third TPG cycles. Preferably a thermophotovoltaic cell is located within any combustor where the effective blackbody radiation of the combustion byproducts are above 2500 degrees Kelvin (preferably above 2800 degrees Kelvin, and particularly preferred above 3200 degrees Kelvin), and more specifically preferred such that the radiant flux is greater than 200 kW per square meter and has an emissivity greater than 0.50 (and more particularly greater than 500 kW per square meter and an emissivity greater than 0.90).

Yet another embodiment of the energy production system is a top cycle furnace having a high radiant flux of greater than 200 kW per square meter and an emissivity of greater than 0.50 (again as noted earlier, the particularly preferred is a radiant flux greater than 500 kW per square meter with an emissivity of greater than 0.90) by utilizing soot and/or soot precursors and at least one preheated oxidant source or fuel. The further inclusion of a first simulated moving bed enables the top cycle furnace to recover waste heat (and preferably configured such that the simulated moving bed chemically reacts with NOx to reduce exhaust emissions) such that the simulated moving bed enables the combustion exhaust to be preheated above the fuels autoignition temperature. A preferred configuration uses at least a partial stream of the combustion exhaust to entrain at least a portion of the fuel to preheat the fuel and to create at least 5 ppm of soot or soot precursors upstream of the top cycle furnace. The particularly preferred top cycle furnace incorporates the aforementioned thermophotovoltaic cell. A thermophotovoltaic cell has optimal performance when the top cycle furnace has a radiant flux at the smallest wavelength possible, thus such a high temperature is best achieved with a NOx reduction system as known in the art and preferably in combination with the simulated moving bed to enable high temperature without the concerns of NOx within the top cycle furnace. The noted furnace, whether it has a thermophotovoltaic cell or not, achieves the advantage of high radiant flux with high emissivity for maximum heat transfer to integrated heat exchanger within the furnace. In other words, the furnace is a boiler of a working fluid for a first or even second TPG cycle. Another configuration further includes a second TPG cycle such that the boiler/furnace wall transfers at least 20 percent of the thermal energy to heat the working fluid of the second TPG cycle.

The preferred TPG cycle utilizes supercritical CO2, with a high side pressure above 2700 psi, as the working fluid to avoid the phase change non-linearity associated with steam. The lack of non-linearity for supercritical CO2 uniquely takes advantage of homogeneous combustion, particularly flameless combustion having high radiant flux and emissivity. The result is the CO2 heat exchanger is at least 60 percent smaller than a comparable heat exchanger when the working fluid is water/steam. The particularly preferred furnace/boiler with integrated heat exchanger is over 75 percent smaller than a traditional steam boiler, and the specifically preferred furnace/boiler with integrated heat exchanger is over 85 percent smaller. An additional heat exchanger downstream of the supercritical CO2 TPG cycle expander transfers thermal energy to preheat the furnace oxidant above the fuels ignition temperature and then a partial stream of the combustion exhaust dilutes and preheats the fuel above the fuels autoignition temperature. A preferred embodiment further includes a compressor to compress the oxidant source that is then preheated by thermal energy transferred by the first simulated moving bed, and the particularly preferred simulated moving bed has a medium that reacts with carbon dioxide to create an exothermic reaction.

Yet another embodiment is a first TPG cycle, which is an open Brayton cycle that has a combustor burning fuel that is diluted with preheated CO2 (which is preferably heated by waste heat from a second TPG cycle. The preferred configuration also includes a CO2 capture system that when combined with a boost pump utilizes at least some of the CO2 captured by the capture system as a partial CO2 source. This captured CO2 is used to maintain inventory control (i.e., to add CO2) of the CO2 within the second TPG cycle such that the supercritical CO2 as the working fluid is replenished, and the second TPG cycle also has a CO2 exhaust port to remove CO2 and regulate the mass of CO2 within the second TPG cycle. The pump or compressor from the second TPG cycle pressurizes the CO2 to at least 5 psi above the CO2 injection point. Some CO2 is optimally diverted away from the second TPG cycle to dilute the fuel source. The preferred configuration is such that the waste heat exchanger transfers waste heat from the first TPG cycle to the second TPG cycle. At least a partial CO2 source is injected upstream of the second TPG cycle pump to add CO2 working fluid within the second TPG cycle in order to achieve the high-side and low-side pressure state points in equilibrium with CO2 discharged to dilute the fuel source and CO2 leaked through the expander and/or pump/compressor of the second TPG cycle. An additional boost pump and a CO2 exhaust port regulate the mass of CO2 within any of the supercritical CO2 TPG cycles.

Every configuration and embodiment has a control system and method of control to operate the TPG cycle(s) and to obtain optimal control of a combined TPG top cycle such that a first TPG cycle that obtains thermal energy from a combustion stage and a working fluid where the combustion exhaust yields waste heat as a byproduct. A downstream furnace has a temperature setpoint such that the second stage working fluid results from further heating by another combustion stage that utilizes/consumes waste heat from the first combustion stage in the form of the byproduct exhaust. Additional oxidant is combusted by the second stage of combustion yielding additional exhaust. The control system executes a series of steps including: adding a quantity of fuel and oxidant to the first combustion stage to yield a first stage of combustion exhaust having a first stage exhaust temperature; adding additional oxidant to the second combustion stage to yield a second stage combustion exhaust having a second stage exhaust temperature at least 10 degrees Celsius greater than the furnace temperature setpoint.

Turning to FIG. 1, FIG. 1 is a sequential flow diagram of one embodiment of a top cycle power generator 10 with integral furnace 20 in accordance with the present invention to yield power 7 (i.e., in the form of electricity, mechanical energy, etc.). In the embodiment of FIG. 1 beginning with the combustion exhaust 8 being discharged from the top cycle power generator 10 into a furnace 20. The velocity of the combustion exhaust 8 relative to the combustion speed is controlled depending on the type of furnace 20. In a furnace that requires predominantly heat transfer from convection and/or conduction, the combustion exhaust 8 is comprised of virtually all combustion byproducts and negligible levels of non-combusted fuel 5. The fuel to air ratio for a furnace for convection and/or conduction heat transfer, particularly where a secondary thermal energy consumer is present that effectively utilizes at least 80% (and preferably over 90%) of the waste heat, has excess combustion air as compared to fuel of at least 1%. In a furnace that requires predominantly heat transfer from radiative flux, the combustion exhaust 8 upstream of the furnace 20 is comprised of at least 300 ppm of soot (i.e., non-combusted fuel) to yield a homogeneous highly radiative flameless combustion (with a flux of greater than 200 kW per square meter, and an emissivity greater than 0.1. The fuel 5 and oxidant source 6 which can be from the natural composition of air, approximately 21% oxygen, up to 100% pure oxygen where the oxygen generator is from devices known in the art from cryogenic separators to ion transfer membranes, or monoatomic oxygen. The combustion exhaust completes the combustion process within the furnace 20 in order to maximize the emissivity of the combustion exhaust gas and thus to maximize radiant heat transfer rates. Combustion within the top cycle 10 provides significant residence time for air/oxygen and fuel to mix, effective preheating of air/oxygen and fuel to mix to achieve homogeneous flameless combustion within the furnace 20. The preferred discharge temperature downstream of the top cycle power generator 10 is above the autoignition temperature of the fuel 5, and preferably above 2000 degrees Fahrenheit. The preferred top cycle power generator 10 is at least comprised of a ramjet expander, and preferably an inside-out ramjet. A particularly preferred top cycle power generator 10 also utilizes a ramjet compressor, also preferable an inside-out ramjet. Another embodiment of a top cycle power generator 10 is a hybrid multijunction photovoltaic cell tuned to a blackbody emission temperature of greater than 3000 degrees Kelvin.

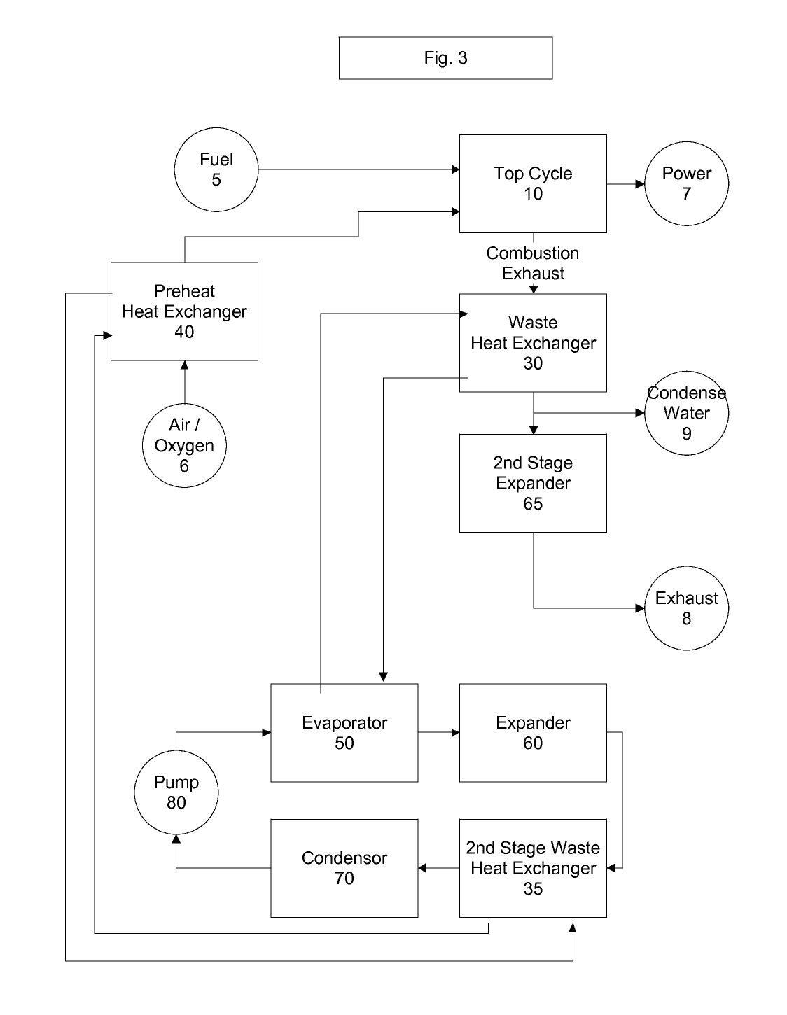

Turning to FIG. 2, FIG. 2 is a sequential flow diagram of one embodiment of a top cycle power generator 10 with integral furnace 20 in accordance with the present invention to yield power 7 (i.e., in the form of electricity, mechanical energy, etc.). In the embodiment of FIG. 2 beginning with the combustion exhaust 8 being discharged from the top cycle power generator 10 into a furnace 20. The process flow and objectives within FIG. 2 are equivalent to FIG. 1, with the additional components of a waste heat exchanger 30 to preheat the oxidant source air/oxygen 6 through a preheat heat exchanger 40. A preferred embodiment for the preheating of oxidant source 6 is depicted in FIG. 7, particularly for the top cycle power generator 10 being a Brayton cycle such as a ramjet, where the preheat heat exchanger 40 is downstream of the top cycle compressor 11 and upstream of the top cycle combustor 12. Specifically in the ramjet, where the mixing and combustion of the fuel 5 with the oxidant source 6 must occur very quickly due to the brief resident time within the combustor 12. The combination of preheating the oxidant source 6 to above the fuels 5 autoignition temperature in order to overcome flame instability issues within ramjet combustion stages.

Turning to FIG. 3, FIG. 3 is a sequential flow diagram of one embodiment of a top cycle power generator 10 with integral evaporator 50 to transfer thermal energy into the supercritical CO2 bottom cycle, which consists of a power generating expander 60 downstream of the evaporator 50. The expander 60 is in thermal communication with the downstream 2nd stage waste heat exchanger 35 that transfers waste heat from this bottom cycle back to the top cycle through the preheat heat exchanger 40. The combustion exhaust downstream of the top cycle 10 has a discharge temperature of greater than 1000 degrees Fahrenheit and preferably greater than 2000 degrees Fahrenheit. The bottom cycle being a supercritical CO2 power generating cycle, having a working fluid top side pressure of greater than 2000 psi (and preferably greater than 2700 psi) and temperature greater than 650 degrees Celsius extracts its thermal energy through the waste heat exchanger 30 upstream of the 2nd stage expander 65 (of the top cycle) due to the combination of the high temperature and pressure state point. This extreme state point requires the waste heat exchanger 30 to be made of ceramics or refractory metals, thus maximum heat transfer occurs prior to the 2nd stage expander 65 to minimize the size of the waste heat exchanger 30 due to higher density and higher temperature of the top cycle combustion exhaust relative to the state point downstream of the 2nd stage expander 65. Furthermore, the transfer of thermal energy out of the top cycle combustion exhaust 8 enables the water vapor combustion byproduct to be condensed into water 9 to eliminate damage to the 2nd stage expander 65. The preferred state point upstream of the top cycle is above the supercritical pressure of CO2, and particularly preferred such that the state point downstream of the top cycle is also above the supercritical pressure of CO2. It is understood that the pump 80 can be substituted with a turbopump and is operating as a Rankine cycle. It is also understood that the bottom cycle can, and is likely to be a combined cycle that is comprised of a CO2 cycle as the top cycle within this bottom cycle and a steam cycle as the bottom cycle within this bottom cycle. Alternatively, the CO2 cycle is a cascaded cycle as known in the art. The bottom cycle as depicted in FIG. 3 is void of a recuperator in order to minimize the number of heat exchangers at working fluid pressures of greater than 2000 psi (and particularly above 2700 psi). The preheating of the oxidant source 6 is identical as depicted in FIG. 2.

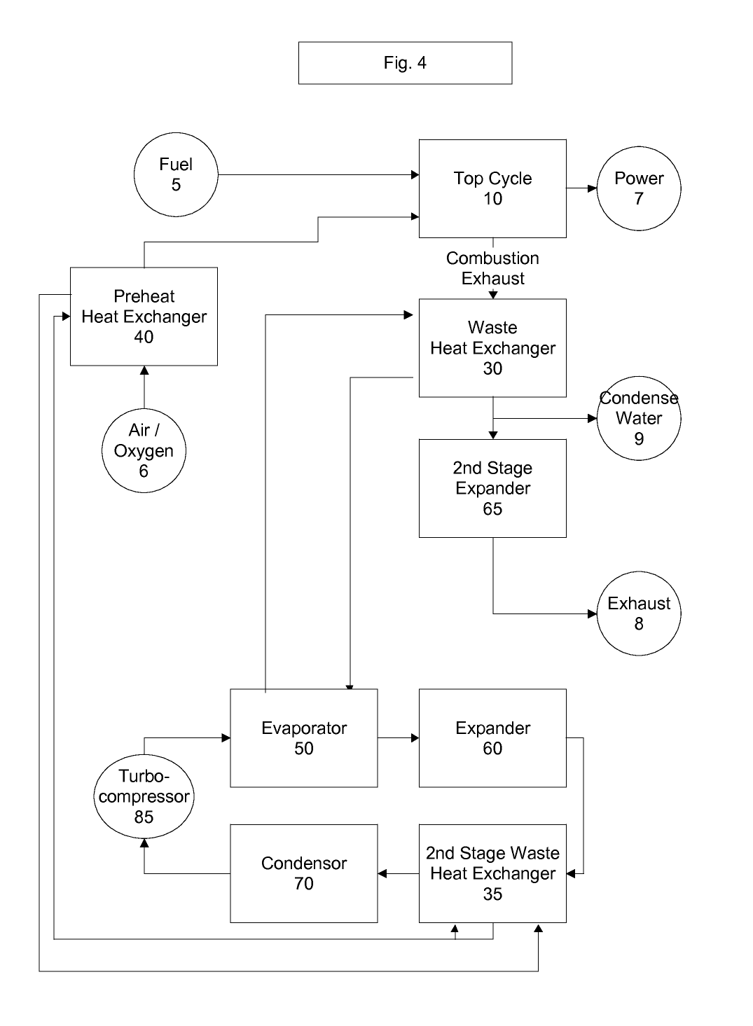

Turning to FIG. 4, it is identical to FIG. 3 with the exception of the pump 80 within FIG. 3 is substituted with turbocompressor 85 within FIG. 4 with the latter particularly preferred as an inside-out ramjet compressor, thus the bottom cycle is operating as a Brayton cycle.

Turning to FIG. 5, FIG. 5 is a sequential flow diagram of one embodiment of a top cycle power generator 10 with integral furnace 20 in accordance with the present invention to yield power 7 (i.e., in the form of electricity, mechanical energy, etc.) and a high radiative with high emissivity combustion within downstream furnace 20 of the top cycle power generator 10. In the embodiment of FIG. 1 beginning with the combustion exhaust 8 being discharged from the top cycle power generator 10 into the furnace 20 subsequently having additional fuel 5 and a soot source 21 in order to achieve homogeneous flameless combustion having energy flux greater than 100 kW per square meter (preferably greater than 200 kW per square meter up to greater than 500 kW per square meter). The soot enables the combustion exhaust from the top cycle 10 to achieve the high emissivity required within the furnace 10. The preferred embodiment is such that the fuel 5 to oxidant 6 ratio is lean (i.e., air is at a stoichiometric excess of at least 1%, preferably at least 5%) that has the benefit of preheating the non-combusted oxygen such that the oxygen temperature is above the autoignition temperature of the fuel 5 entering the furnace 20. The combustion exhaust downstream of the furnace 20 is at least partially recovered through a waste heat exchanger 30 through a preheat heat exchanger 40 to preheat the oxidant source 6 prior to entering the top cycle 10. The fuel 5, though not depicted in FIG. 5, can be preheated as known in the art preferably as a diluted fuel flow (such that the fuel is diluted with at least a stoichiometric deficient ratio of oxygen) to enhance flameless combustion within the top cycle 10 as well as within the furnace 20.

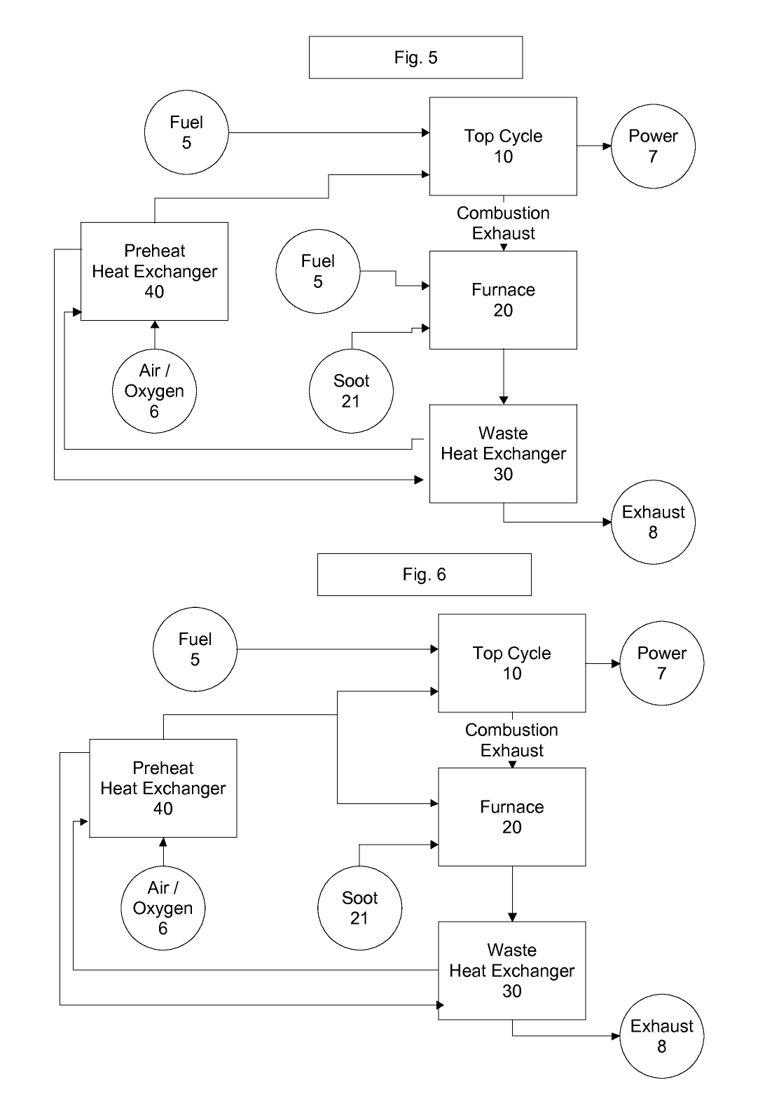

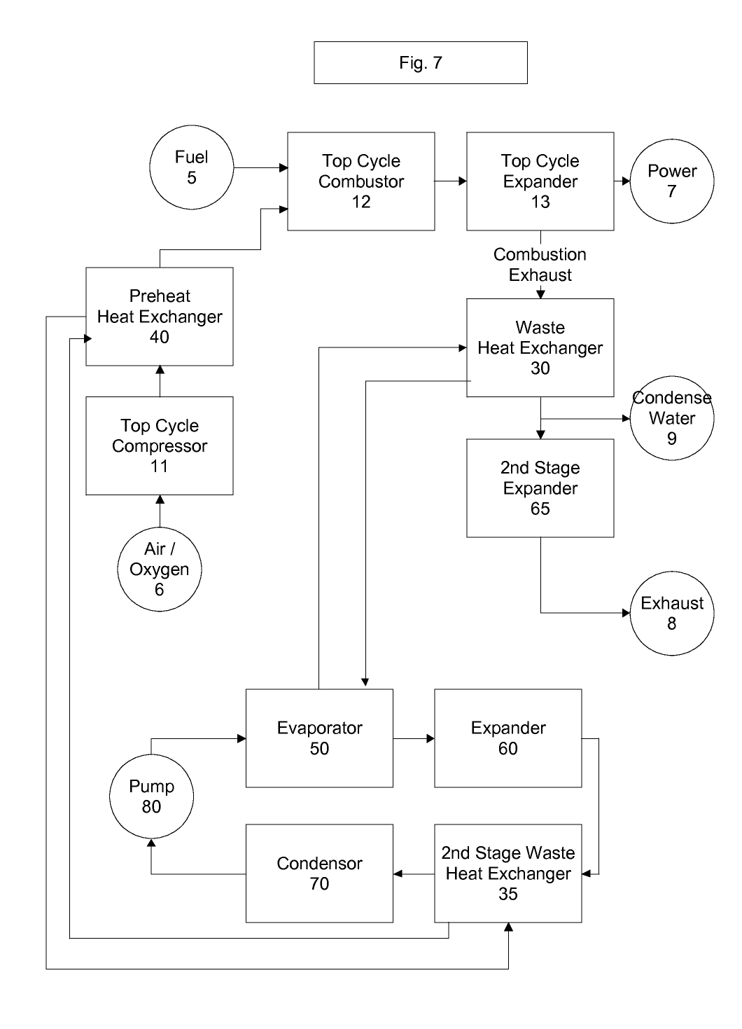

Turning to FIG. 6, FIG. 6 is a sequential flow diagram of one embodiment of a top cycle power generator 10 with integral furnace in accordance with the present invention. The depicted sequential flow within FIG. 6 is virtually identical with FIG. 5 with the exception of preheating of oxidant source 6 for both the top cycle 10 and the furnace 20. The fuel 5 is rich, relative to the stoichiometric ratio of oxidant source within the top cycle 10, that has the benefit of preheating the fuel in a dilute form prior to reaching the furnace 20 such that the conditions exist for a highly radiative and emissive flameless combustion occurs within the furnace 20.

Turning to FIG. 7, FIG. 7 is a sequential flow diagram of one embodiment of a top cycle power generator 10 with integral evaporator 50 to transfer thermal energy into the supercritical CO2 bottom cycle, which consists of a power generating expander 60 downstream of the evaporator 50. The expander 60 is in thermal communication with the downstream 2nd stage waste heat exchanger 35 that transfers waste heat from this bottom cycle back to the top cycle through the preheat heat exchanger 40. In this embodiment, as compared to FIG. 3, the bottom cycle waste heat is transferred to the top cycle downstream of the oxidant compressor 11. The then preheated oxidant is mixed with the fuel 5 within the top cycle combustor 12. The combustion exhaust downstream of the top cycle 10 has a discharge temperature of greater than 1000 degrees Fahrenheit and preferably greater than 2000 degrees Fahrenheit. The bottom cycle being a supercritical CO2 power generating cycle, having a working fluid top side pressure of greater than 2000 psi (and preferably greater than 2700 psi) and temperature greater than 650 degrees Celsius extracts its thermal energy through the waste heat exchanger 30 upstream of the 2nd stage expander 65 (of the top cycle) due to the combination of the high temperature and pressure state point. This extreme state point requires the waste heat exchanger 30 to be made of ceramics or refractory metals, thus maximum heat transfer occurs prior to the 2nd stage expander 65 to minimize the size of the waste heat exchanger 30 due to higher density and higher temperature of the top cycle combustion exhaust relative to the state point downstream of the 2nd stage expander 65. Furthermore, the transfer of thermal energy out of the top cycle combustion exhaust 8 enables the water vapor combustion byproduct to be condensed into water 9 to eliminate damage to the 2nd stage expander 65. The preferred state point upstream of the top cycle is above the supercritical pressure of CO2, and particularly preferred such that the state point downstream of the top cycle is also above the supercritical pressure of CO2. It is understood that the pump 80 can be substituted with a turbopump and is operating as a Rankine cycle. It is also understood that the bottom cycle can, and is likely to be a combined cycle that is comprised of a CO2 cycle as the top cycle within this bottom cycle and a steam cycle as the bottom cycle within this bottom cycle. Alternatively, the CO2 cycle is a cascaded cycle as known in the art. The bottom cycle as depicted in FIG. 7 is void of a recuperator in order to minimize the number of heat exchangers at working fluid pressures of greater than 2000 psi (and particularly above 2700 psi). The preheating of the oxidant source 6 is identical as depicted in FIG. 2. Though not depicted in FIG. 7, it is understood that a smaller recuperator downstream of the 2nd stage waste heat exchanger 35 to transfer thermal energy downstream of the pump 80 has the ability to increase the system efficiency. The drawbacks to this configuration are such that the temperature of the recuperator is always less than the temperature at the top cycle waste heat exchanger 30, therefore the gains are solely within the 2nd stage expander 65 such that the enthalpy at the state point prior to the 2nd stage expander 65 is incrementally higher than with the recuperator. The preferred embodiment is such that the top cycle high side pressure is above the supercritical pressure of CO2, and particularly such that the top cycle pressure upstream of the 2nd stage expander 65 is also above the supercritical pressure of CO2.

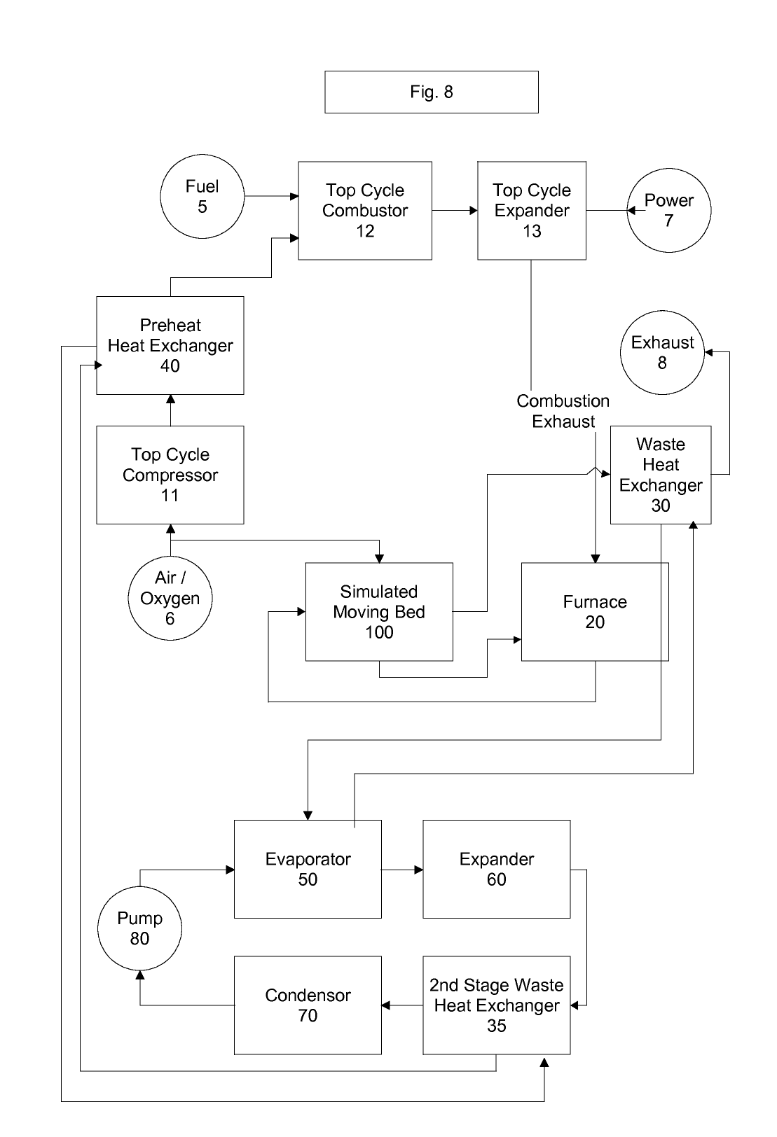

Turning to FIG. 8, FIG. 8 is a sequential flow diagram of one embodiment of a top cycle power generator 10 that transfers thermal energy into the supercritical CO2 bottom cycle through the bottom cycle evaporator 50, but only after the waste heat of the top cycle is utilized in part through the furnace 20. In this embodiment as compared to FIG. 7, the top cycle combustion exhaust is discharged into the furnace 20 such that the fuel 5 (that enters the top cycle as a rich stream, i.e., stochimetric excess of fuel by at least 1%, preferably such that the fuel mass flow rate is sufficient to eliminate additional fuel being added to meet the radiative requirements of the furnace 20) is preheated to above it's autoignition point. All of the now combustion exhaust from the furnace 20 now enters the simulated moving bed 100 to provide waste heat recovery as a preheat of additional oxidant from the oxidant source 6. The preferred embodiment is such that oxidant source is at least 40% oxygen on a mass fraction, and particularly preferred at least 50% oxygen on a mass fraction, and specifically preferred at least 90% oxygen on a mass fraction. The simulated moving bed 100, which is comprised of an oxide thermal media, is uniquely capable of preheating the rich oxygen source without the material (i.e., such as stainless or refractory metals) from oxidizing. The waste heat from the combustion exhaust, which is now downstream of the simulated moving bed 100 is transferred to the CO2 bottom cycle through the waste heat exchanger 30. It is understood that the waste heat exchanger can and is most likely to be the evaporator 50 of the bottom cycle, as the use of CO2 as the working fluid has the unique capabilities of operating within temperatures that exceed 400 degrees Celsius (and particularly above 650 degrees Celsius, and specifically preferred above 800 degrees Celsius). The expander 60 is in thermal communication with the downstream 2nd stage waste heat exchanger 35 that transfers waste heat from this bottom cycle back to the top cycle through the preheat heat exchanger 40. In this embodiment, as compared to FIG. 3, the bottom cycle waste heat is transferred to the top cycle downstream of the oxidant compressor 11. The then preheated oxidant is mixed with the fuel 5 within the top cycle combustor 12. The combustion exhaust downstream of the top cycle 10 has a discharge temperature of greater than 1000 degrees Fahrenheit and preferably greater than 2000 degrees Fahrenheit. The bottom cycle being a supercritical CO2 power generating cycle, having a working fluid top side pressure of greater than 2000 psi (and preferably greater than 2700 psi) and temperature greater than 650 degrees Celsius extracts its thermal energy through the waste heat exchanger 30 upstream of the 2nd stage expander 65 (of the top cycle) due to the combination of the high temperature and pressure state point. This extreme state point requires the waste heat exchanger 30 to be made of ceramics or refractory metals, thus maximum heat transfer occurs prior to the 2nd stage expander 65 to minimize the size of the waste heat exchanger 30 due to higher density and higher temperature of the top cycle combustion exhaust relative to the state point downstream of the 2nd stage expander 65. The preferred state point upstream of the top cycle is above the supercritical pressure of CO2, and particularly preferred such that the state point downstream of the top cycle is also above the supercritical pressure of CO2. It is understood that the pump 80 can be substituted with a turbopump and is operating as a Rankine cycle. It is also understood that the bottom cycle can, and is likely to be a combined cycle that is comprised of a CO2 cycle as the top cycle within this bottom cycle and a steam cycle as the bottom cycle within this bottom cycle. Alternatively, the CO2 cycle is a cascaded cycle as known in the art. The bottom cycle as depicted in FIG. 7 is void of a recuperator in order to minimize the number of heat exchangers at working fluid pressures of greater than 2000 psi (and particularly above 2700 psi). The preheating of the oxidant source 6 is identical as depicted in FIG. 2. Though not depicted in FIG. 8, it is understood that a smaller recuperator downstream of the 2nd stage waste heat exchanger 35 to transfer thermal energy downstream of the pump 80 has the ability to increase the system efficiency. The drawbacks to this configuration are such that the temperature of the recuperator is always less than the temperature at the top cycle waste heat exchanger 30, therefore the gains are solely within the 2nd stage expander 65 such that the enthalpy at the state point prior to the 2nd stage expander 65 is incrementally higher than with the recuperator. The preferred embodiment is such that the top cycle high side pressure is above the supercritical pressure of CO2, and particularly such that the top cycle pressure upstream of the 2nd stage expander 65 is also above the supercritical pressure of CO2.

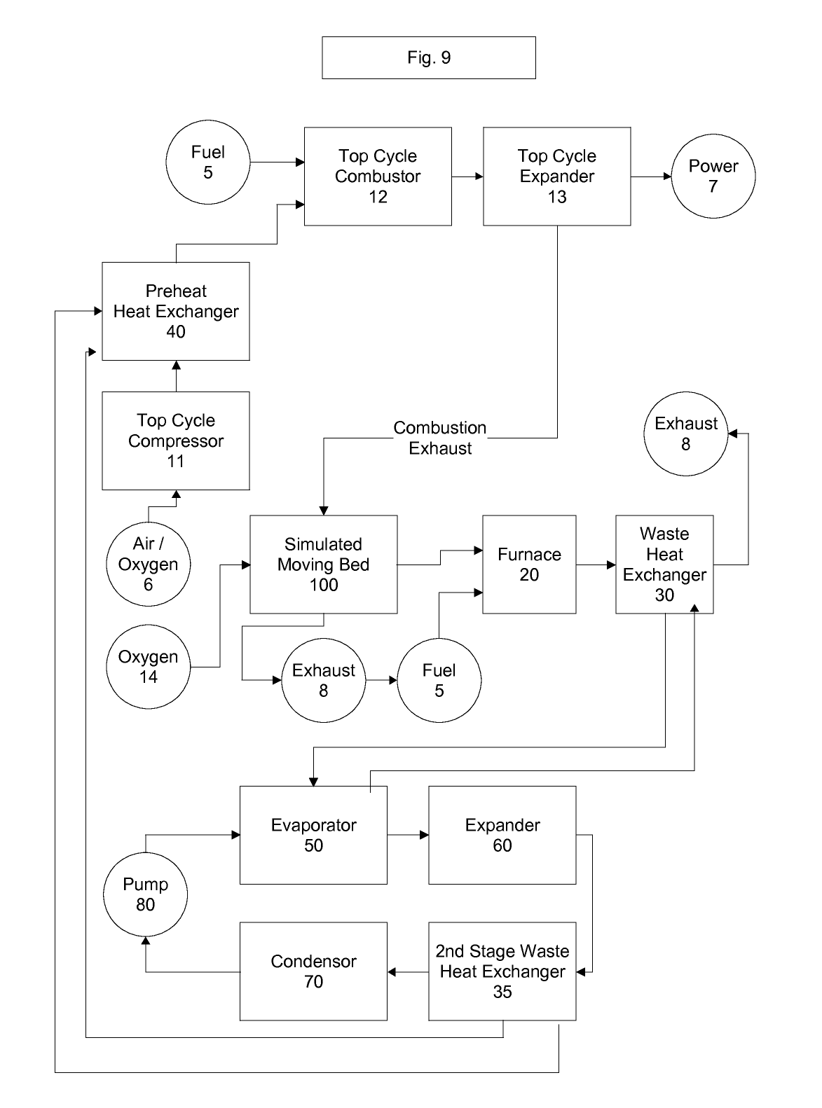

Turning to FIG. 9, FIG. 9 is a sequential flow diagram of one embodiment of a top cycle power generator 10 that transfers thermal energy into the supercritical CO2 bottom cycle through the bottom cycle evaporator 50, but only after the waste heat of the top cycle is utilized in part through the furnace 20. In this embodiment as compared to FIG. 8, the top cycle combustion exhaust is discharged into the simulated moving bed 100 prior to subsequent discharge into the furnace 20. The fuel 5 (that enters the top cycle is a rich stream, i.e., stochimetric excess of fuel by at least 1%, preferably such that the fuel mass flow rate is sufficient to eliminate additional fuel being added to meet the radiative requirements of the furnace 20) is preheated to above it's autoignition point. All of the top cycle combustion exhaust first serves to preheat an oxidant source, preferably an enriched oxygen gas 14 or a relatively pure (at least 90% oxygen on a mass basis) to above the autoignition temperature of the fuel 5 and then subsequently the preheated oxygen is injected into the furnace 20 (that can be either through a burner or simply an injection port/nozzle as both the oxygen and fuel are above the autoignition temperature. The top cycle combustion exhaust downstream of the simulated moving bed 100 is preferably still above the autoignition temperature but significantly below stoichiometric levels of oxygen such that limited if any fuel combustion takes place prior to injection into the furnace 20. The preferred embodiment is such that oxidant source is at least 40% oxygen on a mass fraction, and particularly preferred at least 50% oxygen on a mass fraction, and specifically preferred at least 90% oxygen on a mass fraction. The waste heat from the combustion exhaust, which is now downstream of the furnace 20 is transferred to the CO2 bottom cycle through the waste heat exchanger 30. It is understood that the waste heat exchanger can and is most likely to be the evaporator 50 of the bottom cycle, as the use of CO2 as the working fluid has the unique capabilities of operating within temperatures that exceed 400 degrees Celsius (and particularly above 650 degrees Celsius, and specifically preferred above 800 degrees Celsius). The expander 60 is in thermal communication with the downstream 2nd stage waste heat exchanger 35 that transfers waste heat from this bottom cycle back to the top cycle through the preheat heat exchanger 40. In this embodiment, as compared to FIG. 3, the bottom cycle waste heat is transferred to the top cycle downstream of the oxidant compressor 11. The then preheated oxidant is mixed with the fuel 5 within the top cycle combustor 12. The combustion exhaust downstream of the top cycle 10 has a discharge temperature of greater than 1000 degrees Fahrenheit and preferably greater than 2000 degrees Fahrenheit. The bottom cycle being a supercritical CO2 power generating cycle, having a working fluid top side pressure of greater than 2000 psi (and preferably greater than 2700 psi) and temperature greater than 650 degrees Celsius extracts its thermal energy through the waste heat exchanger 30 upstream of the 2nd stage expander 65 (of the top cycle) due to the combination of the high temperature and pressure state point. This extreme state point requires the waste heat exchanger 30 to be made of ceramics or refractory metals, thus maximum heat transfer occurs prior to the 2nd stage expander 65 to minimize the size of the waste heat exchanger 30 due to higher density and higher temperature of the top cycle combustion exhaust relative to the state point downstream of the 2nd stage expander 65. The preferred state point upstream of the top cycle is above the supercritical pressure of CO2, and particularly preferred such that the state point downstream of the top cycle is also above the supercritical pressure of CO2. It is understood that the pump 80 can be substituted with a turbopump and is operating as a Rankine cycle. It is also understood that the bottom cycle can, and is likely to be a combined cycle that is comprised of a CO2 cycle as the top cycle within this bottom cycle and a steam cycle as the bottom cycle within this bottom cycle. Alternatively, the CO2 cycle is a cascaded cycle as known in the art. The bottom cycle as depicted in FIG. 9 is void of a recuperator in order to minimize the number of heat exchangers at working fluid pressures of greater than 2000 psi (and particularly above 2700 psi). The preheating of the oxidant source 6 is identical as depicted in FIG. 2. Though not depicted in FIG. 9, it is understood that a smaller recuperator downstream of the 2nd stage waste heat exchanger 35 to transfer thermal energy downstream of the pump 80 has the ability to increase the system efficiency. The drawbacks to this configuration are such that the temperature of the recuperator is always less than the temperature at the top cycle waste heat exchanger 30, therefore the gains are solely within the 2nd stage expander 65 such that the enthalpy at the state point prior to the 2nd stage expander 65 is incrementally higher than with the recuperator. The preferred embodiment is such that the top cycle high side pressure is above the supercritical pressure of CO2, and particularly such that the top cycle pressure upstream of the 2nd stage expander 65 is also above the supercritical pressure of CO2. The result of this embodiment is that virtually all, preferably greater than 90% and specifically preferably greater than 95% of the combustion exhaust waste heat from the top cycle power generator is utilized within either the downstream furnace 20 or captured for the bottom cycle CO2 power generator.

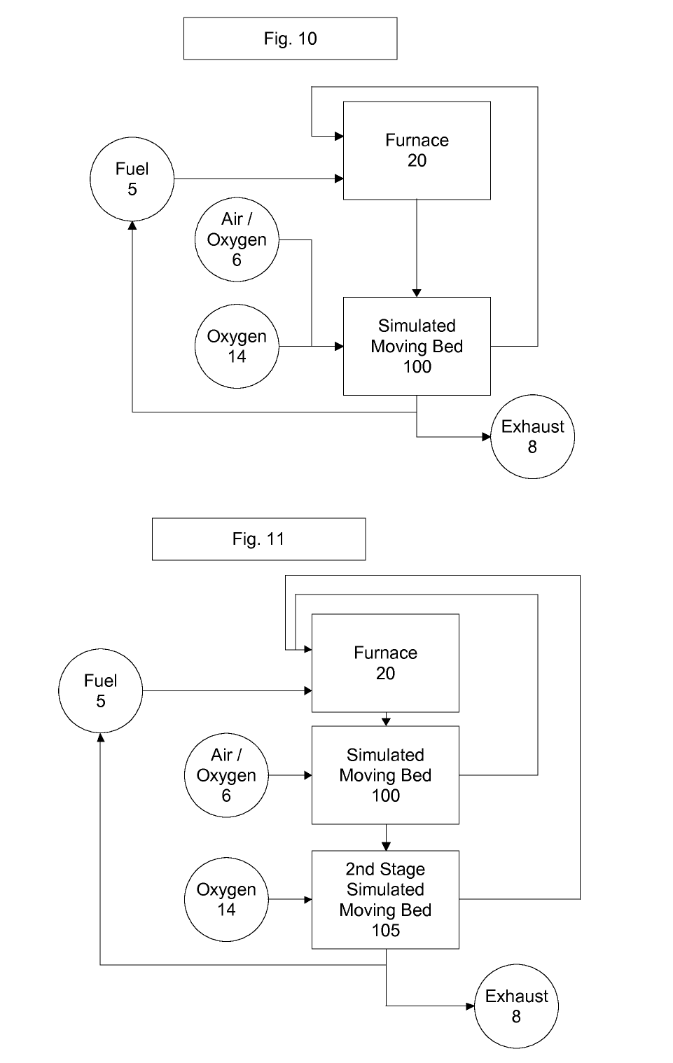

Turning to FIG. 10, FIG. 10 is a sequential flow diagram of one embodiment of a high temperature furnace, which can be optionally configured with thermophotovoltaic cells to provide power generation. The furnace 20 combusts both preheated and dilute air 6 with additional oxygen 14 through a simulated moving bed 100 and the fuel through partial recirculation of the combustion exhaust waste heat. A portion of the then remaining combustion exhaust downstream of the simulated moving bed 100, though not depicted, can be recirculated with the now preheated air and oxygen, though preferably the stoichiometric equivalent level of combustion byproducts will be discharged to a secondary process driven by this waste heat. Again, though not depicted, it is anticipated that the fuel 5 can be utilized to combust away particulate matter from the furnace 20 combustion exhaust. This process of combusting away particulate matter can have the fuel 5 either entering the combustion exhaust upstream of the simulated moving bed 100 with the combustion exhaust downstream of the furnace 20, or with the preheated air 6 with or without preheated oxygen 14 downstream of the furnace 20.

Turning to FIG. 11, FIG. 11 is a sequential flow diagram of one embodiment of a high temperature furnace, which can also be optionally configured with thermophotovoltaic cells to provide power generation as in FIG. 10. The furnace 20 combusts both preheated and dilute air 6 through a simulated moving bed 100 and the fuel through partial recirculation of the combustion exhaust waste heat. Additional oxidant of oxygen 14 is preheated through the 2nd stage simulated moving bed 105 as a method to reduce the oxygen temperature such that metal components in contact with this preheated stream has reduced oxidation, in addition to reduced oxidation within the 2nd stage simulated moving bed 105. A portion of the then remaining combustion exhaust downstream of the simulated moving bed 100, though not depicted, can be recirculated with the now preheated air and oxygen, though preferably the stoichiometric equivalent level of combustion byproducts will be discharged to a secondary process driven by this waste heat. Again, though not depicted, it is anticipated that the fuel 5 can be utilized to combust away particulate matter from the furnace 20 combustion exhaust. This process of combusting away particulate matter can have the fuel 5 either entering the combustion exhaust upstream of the simulated moving bed 100 or 2nd stage simulated moving bed 105 with the combustion exhaust downstream of the furnace 20, or with the preheated air 6 with or without preheated oxygen 14 downstream of the furnace 20.

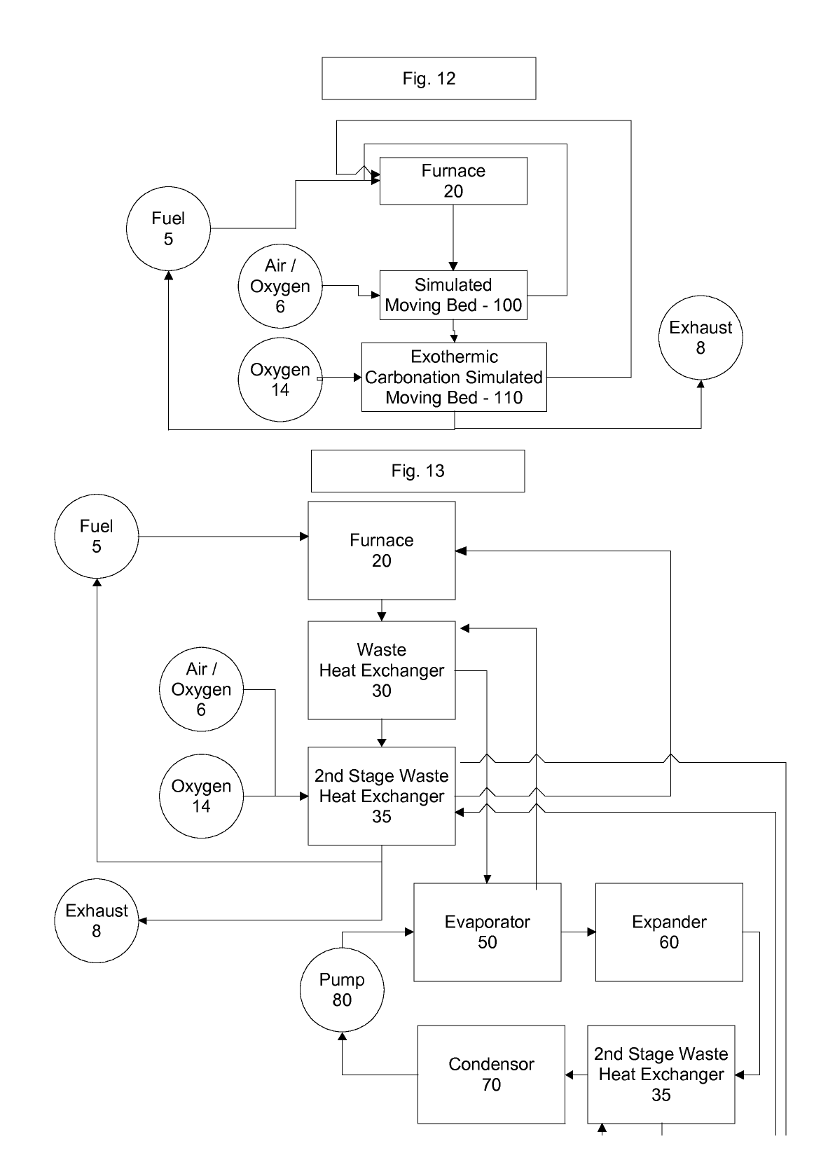

Turning to FIG. 12, FIG. 12 is a sequential flow diagram of one embodiment of a high temperature furnace, which can also be optionally configured with thermophotovoltaic cells to provide power generation as in FIG. 10. The furnace 20 combusts both preheated and dilute air 6 through a simulated moving bed 100 and the fuel through partial recirculation of the combustion exhaust waste heat. Additional oxidant of oxygen 14 is preheated through the exothermic carbonation simulated moving bed 110 as a method to both increase the enthalpy recovered by utilizing a carbonation medium (preferably a mineral carbonation medium) as it reacts with the CO2 of the combustion exhaust of the furnace 20 and to reduce the oxygen temperature such that metal components in contact with this preheated stream has reduced oxidation, in addition to reduced oxidation within the 2nd stage simulated moving bed 105. The preferred combustion exhaust temperature of the furnace 20 downstream of the simulated moving bed 100 is greater than 150 degrees Celsius and preferably above 200 degrees Celsius, but less than 300 degrees Celsius and preferably less than 250 degrees Celsius. A portion of the then remaining combustion exhaust downstream of the simulated moving bed 100, though not depicted, can be recirculated with the now preheated air and oxygen, though preferably the stoichiometric equivalent level of combustion byproducts will be discharged to a secondary process driven by this waste heat. Again, though not depicted, it is anticipated that the fuel 5 can be utilized to combust away particulate matter from the furnace 20 combustion exhaust. This process of combusting away particulate matter can have the fuel 5 either entering the combustion exhaust upstream of the simulated moving bed 100 or 2nd stage simulated moving bed 105 with the combustion exhaust downstream of the furnace 20, or with the preheated air 6 with or without preheated oxygen 14 downstream of the furnace 20.

Turning to FIG. 13, FIG. 13 is a sequential flow diagram of one embodiment of a high temperature furnace, which can also be optionally configured with thermophotovoltaic cells to provide power generation as in FIG. 10. The furnace 20 combusts both preheated and dilute air 6 (with or without additional oxidant being enriched oxygen 14 through a 2nd stage waste heat exchanger 35 and the fuel through partial recirculation of the combustion exhaust waste heat. The combustion exhaust of the furnace 20 has enthalpy transferred through a waste heat exchanger 30 into a bottom cycle CO2 power generation comprised of an evaporator 50 (which can be located downstream of the furnace 20 instead of the waste heat exchanger 30), an expander 60, a 2nd stage waste heat exchanger 35, a condenser 70, and a pump 80 (which can be substituted with a turbocompressor though not depicted). The thermal energy from the furnace 20 combustion exhaust is transferred to the CO2 power generation cycle first (i.e., before the preheat of combustion air 6 with or without additional oxidant 14) for the purpose of reducing oxidation of metal components containing the preheated oxidant to the furnace 20) and to reduce the physical size of the waste heat exchanger 30 (or evaporator 50 when replacing the waste heat exchanger 30) due to the high pressure supercritical CO2 (greater than 1200 psi, preferably greater than 2700 psi, and specifically preferred at greater than 3200 psi) at high temperatures (greater than 650 degrees Celsius, and preferably greater than 1000 degrees Celsius). The preferred exhaust temperature downstream of the waste heat exchanger 30 (or evaporator 50 when substituted for the waste heat exchanger 30) is less than 1500 degrees Celsius (preferably less than 1200 degrees Celsius, specifically preferred less than 1100 degrees Celsius). It is understood, though not depicted that the CO2 power generation system can have a recuperator downstream of the expander 60 to upstream of the evaporator 50 (as known in the art) as a function of the furnace 20 efficiency, the thermophotovoltaic efficiency within the furnace 20. As known in the art, the condensor 70 removes thermal energy from CO2 working fluid such that the CO2 at the low side pressure and temperature state point becomes a liquid downstream of the pump 80. The pump 80 then increases the CO2 working fluid operating pressure to a pressure above the supercritical pressure of CO2 (and preferably above 2700 psi, and specifically preferred above 3000 psi). The waste heat from the bottom cycle is utilized to preheat the combustion air for the furnace 20 that consists of air 6 and optionally (and preferably oxygen enriched source 14) through the 2nd stage waste heat exchanger 35. The fuel 5 is optionally, though preferably, preheated and diluted with a partial stream of the combustion exhaust.

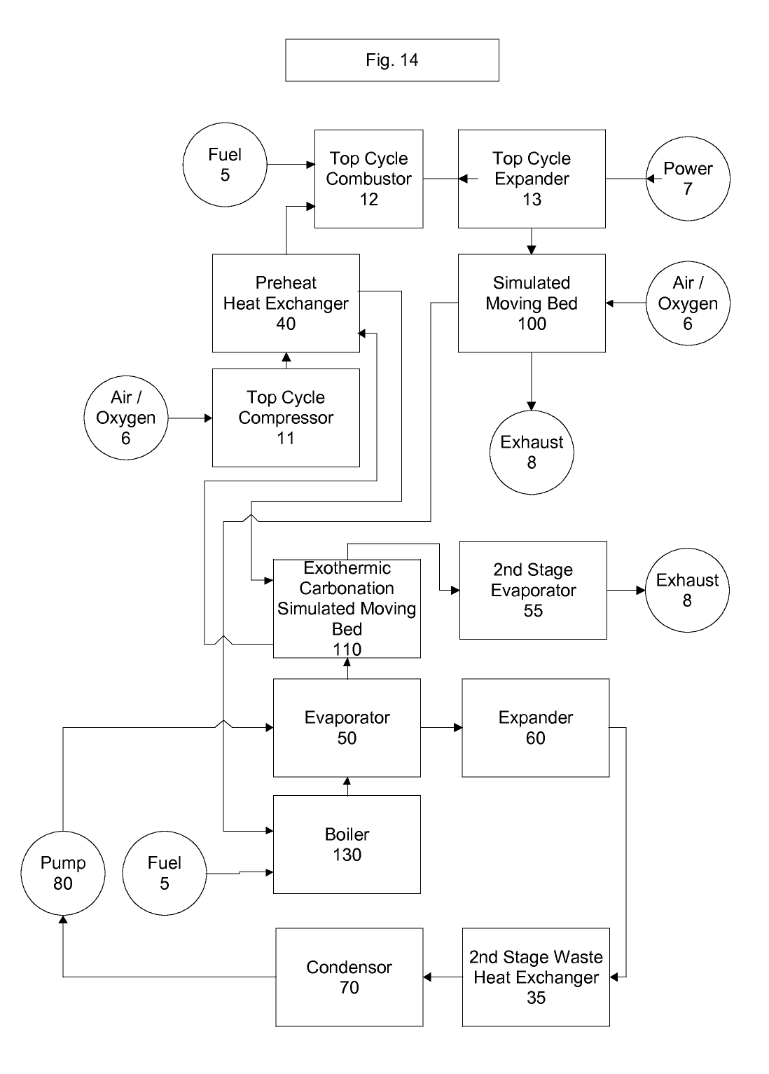

Turning to FIG. 14, FIG. 14 is a sequential flow diagram of one embodiment of a high temperature top cycle power generator that is consisting of top cycle compressor 11, combustor 12, and expander 13. Combustion air 6 (or preferably enriched oxygen, or specifically preferred oxygen above 90% on a weight basis) is preheated through the preheat heat exchanger 40, which obtains thermal energy from the exothermic carbonation reaction within the exothermic carbonation simulated moving bed 110 (preferably at a temperature greater than 200 degrees Celsius, and more specifically greater than 250 degrees Celsius up to 300 degrees Celsius). The now preheated combustion air is mixed with fuel 5 within the top cycle combustor 12, which is preferably adjoining the top cycle expander 13. It is particularly preferred that the top cycle compressor 11 and top cycle expander 13 are ramjet type and more specifically preferred are inside-out ramjet. The combustion exhaust from downstream of the top cycle expander is exhausted into a simulated moving bed 100, where the recovered waste heat is utilized to preheat boiler combustion air 6. Fuel 5 is added within the boiler 130, which can be utilized to directly drive a supercritical CO2 power generator cycle (or a steam cycle, or preferably a combined CO2 and steam cascaded cycle). A preferred embodiment is the use of coal as fuel 5 where the preheated air is above the autoignition temperature of the coal to increase the radiant flux to greater than 200 kW per square meter (preferably above 350 kW per square meter, and more specifically above 500 kW per square meter) with an emissivity of greater than 0.2 (preferably above 0.8, and more specifically above 0.9). The combustion conditions within the boiler 130 having the intense radiant, homogeneous, and flameless combustion in combination with the supercritical CO2 power generation cycle has the result of decreasing the evaporator 50 size by greater than 75% (and more preferred greater than 85%, and more specifically preferred greater than 90%) as compared to a standard as known in the art steam cycle. The use of supercritical CO2, preferably at pressures greater than 3000 psi and temperatures greater than 700 degrees Celsius (more preferred greater than 1000 degrees Celsius) in combination with the high radiant and emissivity boiler 130 reduces the capital costs of the boiler by up to 90% due to the size reduction. It is understood that the supercritical CO2 cycle is a cascaded cycle though not depicted, which is preferably a CO2 2nd top cycle also cascaded cycle and more specifically having an additional steam bottom cycle to the CO2 2nd top cycle. Power generation cycles, whether they are fueled by coal, natural gas, or biomass are operationally more efficient when combined with both the simulated moving bed 100 as combustion air for the bottom cycle boiler 130; and the exothermic carbonation simulated moving bed 110 as a thermal source to the top cycle and sequestering CO2 from either or both the top cycle and bottom cycle. Excess waste heat from the exothermic carbonation reaction is optionally and preferably utilized for yet another power generation cycle as captured through the 2nd stage evaporator 55, which can be a second CO2 power generation, Organic Rankine, steam or ammonia cycle. Waste heat from the bottom cycle downstream of the expander 60 is extracted from the CO2 working fluid through a 2nd stage waste heat exchanger 35 to power yet another power generation cycle as known in the art. The condenser 70, pump 80, and expander 60 operate in an identical manner as depicted in FIG. 13. The result of this configuration as depicted in FIG. 14, is such that a co-located top cycle (e.g., an inside-out ramjet Brayton cycle) with a coal powered bottom cycle with an integrated supercritical CO2 power generation cycle. The particularly preferred embodiment utilizes a simulated moving bed as both an effective and lower cost method to transfer thermal energy between the two cycles while remaining at pressures less than 1200 psi (preferably at pressures less than 600 psi, and more specifically preferred at pressures less than 100 psi).

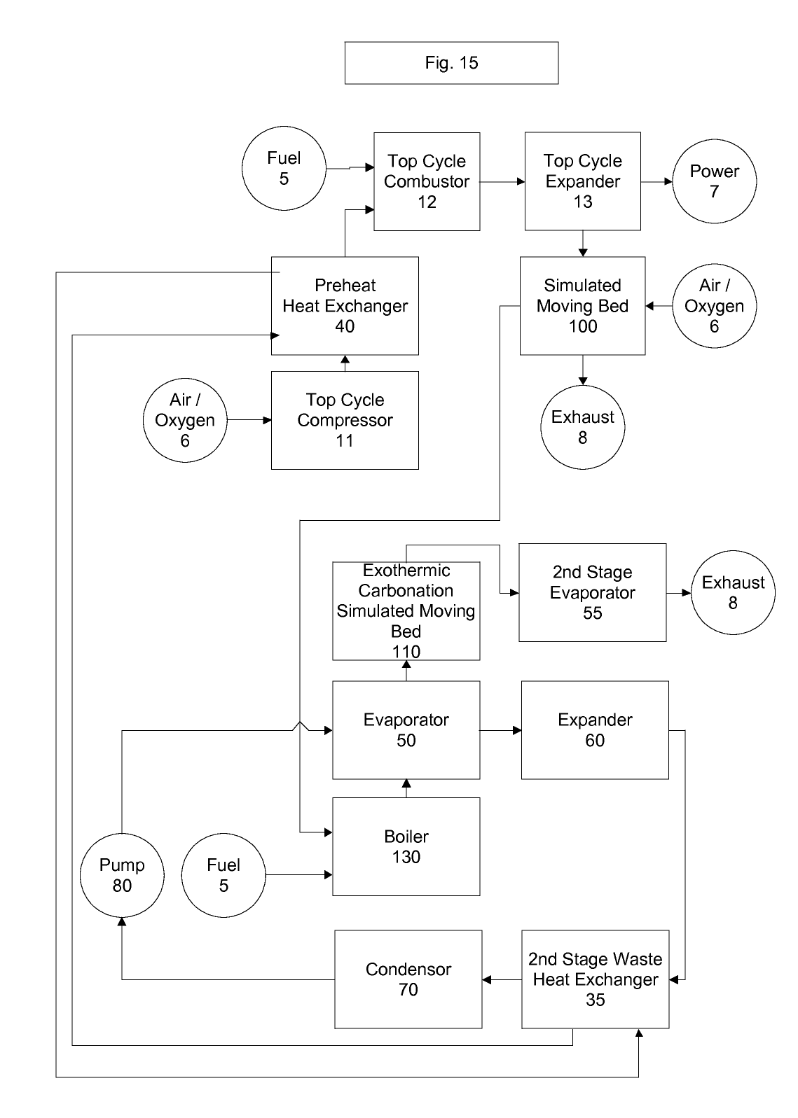

Turning to FIG. 15, FIG. 15 is a sequential flow diagram of one embodiment of a high temperature top cycle power generator that is consisting of top cycle compressor 11, combustor 12, and expander 13, similar to FIG. 14. Combustion air 6 (or preferably enriched oxygen, or specifically preferred oxygen above 90% on a weight basis) is preheated through the preheat heat exchanger 40, which obtains thermal energy from the bottom cycle CO2 power generator through the 2nd stage waste heat exchanger 35 (preferably at a temperature greater than 200 degrees Celsius, and more specifically greater than 250 degrees Celsius up to 300 degrees Celsius). It is understood throughout this figure, and all others, that the combination of two heat exchangers transferring thermal energy from one location to another can be achieved by physical placement of a single heat exchanger with working fluid in one location to the other, in this Figure such as placement of the 2nd stage waste heat exchanger 35 downstream of the top cycle compressor 11 to preheat combustion air/oxygen 6. The now preheated combustion air is mixed with fuel 5 within the top cycle combustor 12, which is preferably adjoining the top cycle expander 13. It is particularly preferred that the top cycle compressor 11 and top cycle expander 13 are ramjet type and more specifically preferred are inside-out ramjet. The combustion exhaust from downstream of the top cycle expander is exhausted into a simulated moving bed 100, where the recovered waste heat is utilized to preheat boiler combustion air 6. Fuel 5 is added within the boiler 130, which can be utilized to directly drive a supercritical CO2 power generator cycle (or a steam cycle, or preferably a combined CO2 and steam cascaded cycle). A preferred embodiment is the use of coal as fuel 5 where the preheated air is above the autoignition temperature of the coal to increase the radiant flux to greater than 200 kW per square meter (preferably above 350 kW per square meter, and more specifically above 500 kW per square meter) with an emissivity of greater than 0.2 (preferably above 0.8, and more specifically above 0.9). The combustion conditions within the boiler 130 having the intense radiant, homogeneous, and flameless combustion in combination with the supercritical CO2 power generation cycle has the result of decreasing the evaporator 50 size by greater than 75% (and more preferred greater than 85%, and more specifically preferred greater than 90%) as compared to a standard as known in the art steam cycle. The use of supercritical CO2, preferably at pressures greater than 3000 psi and temperatures greater than 700 degrees Celsius (more preferred greater than 1000 degrees Celsius) in combination with the high radiant and emissivity boiler 130 reduces the capital costs of the boiler by up to 90% due to the size reduction. It is understood that the supercritical CO2 cycle is a cascaded cycle though not depicted, which is preferably a CO2 2nd top cycle also cascaded cycle and more specifically having an additional steam bottom cycle to the CO2 2nd top cycle. Power generation cycles, whether they are fueled by coal, natural gas, or biomass are operationally more efficient when combined with both the simulated moving bed 100 as combustion air for the bottom cycle boiler 130; and the exothermic carbonation simulated moving bed 110 as a thermal source to the top cycle and sequestering CO2 from either or both the top cycle and bottom cycle. Excess waste heat from the exothermic carbonation reaction is optionally and preferably utilized for yet another power generation cycle as captured through the 2nd stage evaporator 55, which can be a second CO2 power generation, Organic Rankine, steam or ammonia cycle. Excess waste heat from the bottom cycle downstream of the expander 60 can additionally, though not depicted in this figure be extracted from the CO2 working fluid through a 2nd stage waste heat exchanger 35 to power yet another power generation cycle as known in the art. The condenser 70, pump 80, and expander 60 operate in an identical manner as depicted in FIG. 13. The result of this configuration as depicted in FIG. 14, is such that a co-located top cycle (e.g., an inside-out ramjet Brayton cycle) with a coal powered bottom cycle with an integrated supercritical CO2 power generation cycle. The particularly preferred embodiment utilizes a simulated moving bed as both an effective and lower cost method to transfer thermal energy between the two cycles while remaining at pressures less than 1200 psi (preferably at pressures less than 600 psi, and more specifically preferred at pressures less than 100 psi).

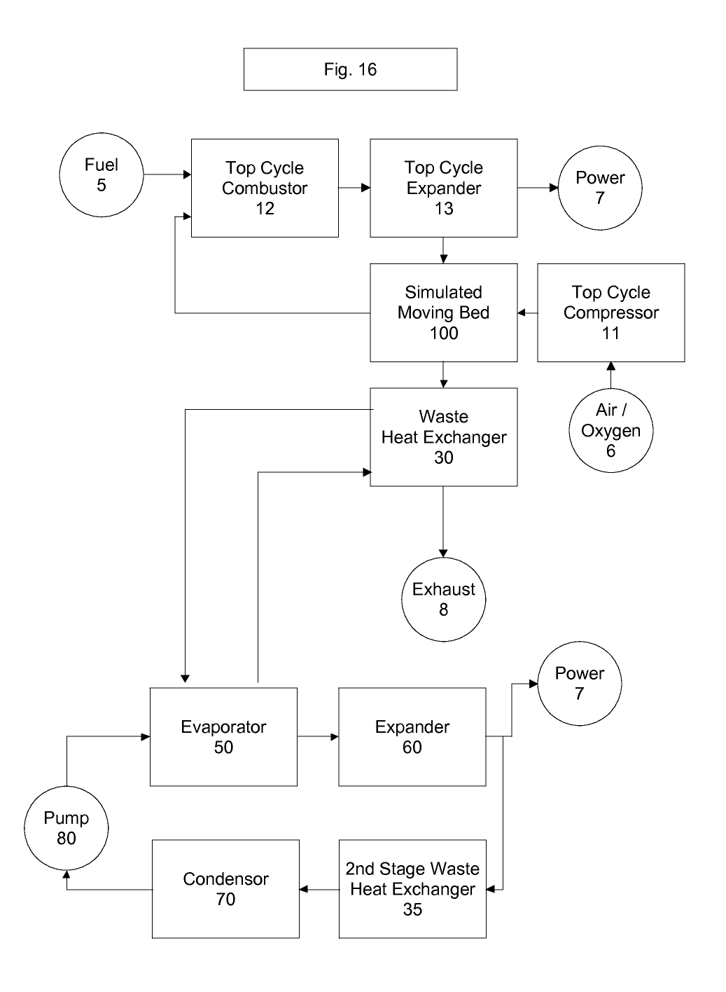

Turning to FIG. 16, FIG. 16 is a sequential flow diagram of one embodiment of a high temperature top cycle power generator that is consisting of top cycle compressor 11, combustor 12, and expander 13, similar to FIG. 14. Combustion air 6 (or preferably enriched oxygen, or specifically preferred oxygen above 90% on a weight basis) is preheated through the simulated moving bed 100, which obtains thermal energy from the top cycle power generator combustion exhaust (preferably at a temperature greater than 400 degrees Celsius, and more specifically greater than 650 degrees Celsius up to 1300 degrees Celsius). It is preferred that the preheated oxidant is above the autoignition temperature of the top cycle, particularly when the combustion takes place at supersonic speeds, such as to limit or reduce flame stability issues (when the oxidant temperature is above autoignition, and preferably the fuel is preheated the combustion is very rapid, homogeneous, and flameless. The balance of the waste heat from the top cycle combustion exhaust is transferred to the supercritical CO2 bottom power generation cycle either through the waste heat exchanger 30 and the evaporator 50 as depicted (or by direct placement of the evaporator 50 downstream of the simulated moving bed 100 combustion exhaust stream. It is further understood, both in this figure and throughout all figures that additional waste heat can be extracted from the combustion exhaust for power generation, thermally activated cooling, process heat, to domestic hot water as known in the art. The supercritical CO2 bottom cycle power generator that is consisting of evaporator 50, then expander 60 (to generator power 7), then an optional 2nd stage waste heat exchanger 35 (or a recuperator as known in the art), then a condenser 70, and finally a pump 80 (or turbocompressor when the low side working fluid remains a vapor) operates as known in the art. The physical placement of the waste heat exchanger 30 downstream of the simulated moving bed 100 is vital to the invention, as a low pressure method of removing thermal energy is essential when the top cycle expander discharges combustion exhaust at temperatures in excess of 1000 degrees Celsius. In the event that the CO2 bottom cycle is not operational, or at partial loads insufficient to maintain the peak temperature of the waste heat exchanger 30 or evaporator 50 below the tensile strength specifications for the operating temperature, an excess amount of oxidant 6 is run through the simulated moving bed 100.

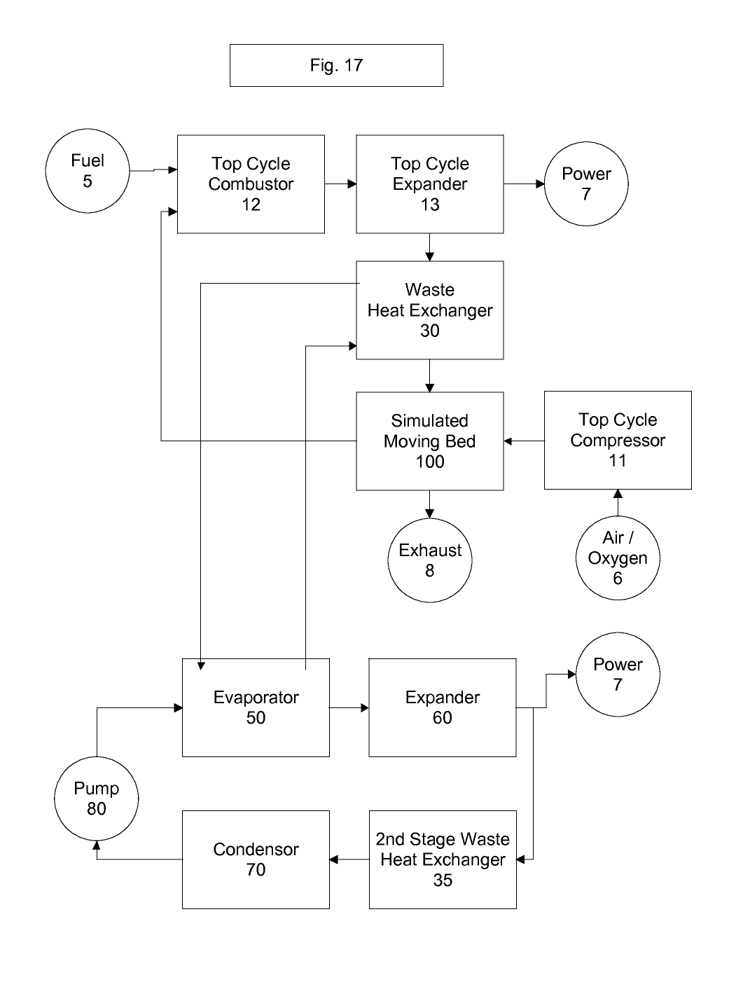

Turning to FIG. 17, FIG. 17 is a sequential flow diagram of another embodiment of a high temperature top cycle power generator that is consisting of top cycle compressor 11, combustor 12, and expander 13, similar to FIG. 16. Combustion air 6 (or preferably enriched oxygen, or specifically preferred oxygen above 90% on a weight basis) is preheated through the simulated moving bed 100, which obtains thermal energy from the top cycle power generator combustion exhaust (preferably at a temperature greater than 400 degrees Celsius, and more specifically greater than 650 degrees Celsius up to 1300 degrees Celsius). In FIG. 17, as compared to FIG. 16 the waste heat exchanger 30 is upstream of the simulated moving bed 100. This has the advantage of enabling a smaller waste heat exchanger 30 as compared to the FIG. 16 embodiment due to the higher exhaust temperature, which is significant as the utilization of high pressure CO2 as the working fluid at such high temperatures demands refractory metals or ceramic heat exchangers. It is preferred that the preheated oxidant is above the autoignition temperature of the top cycle, particularly when the combustion takes place at supersonic speeds, such as to limit or reduce flame stability issues (when the oxidant temperature is above autoignition, and preferably the fuel is preheated the combustion is very rapid, homogeneous, and flameless. The balance of the waste heat from the top cycle combustion exhaust is transferred to the supercritical CO2 bottom power generation cycle either through the waste heat exchanger 30 and the evaporator 50 as depicted (or by direct placement of the evaporator 50 upstream of the simulated moving bed 100 combustion exhaust stream. The supercritical CO2 bottom cycle power generator that is consisting of evaporator 50, then expander 60 (to generator power 7), then an optional 2nd stage waste heat exchanger 35 (or a recuperator as known in the art), then a condenser 70, and finally a pump 80 (or turbocompressor when the low side working fluid remains a vapor) operates as known in the art.

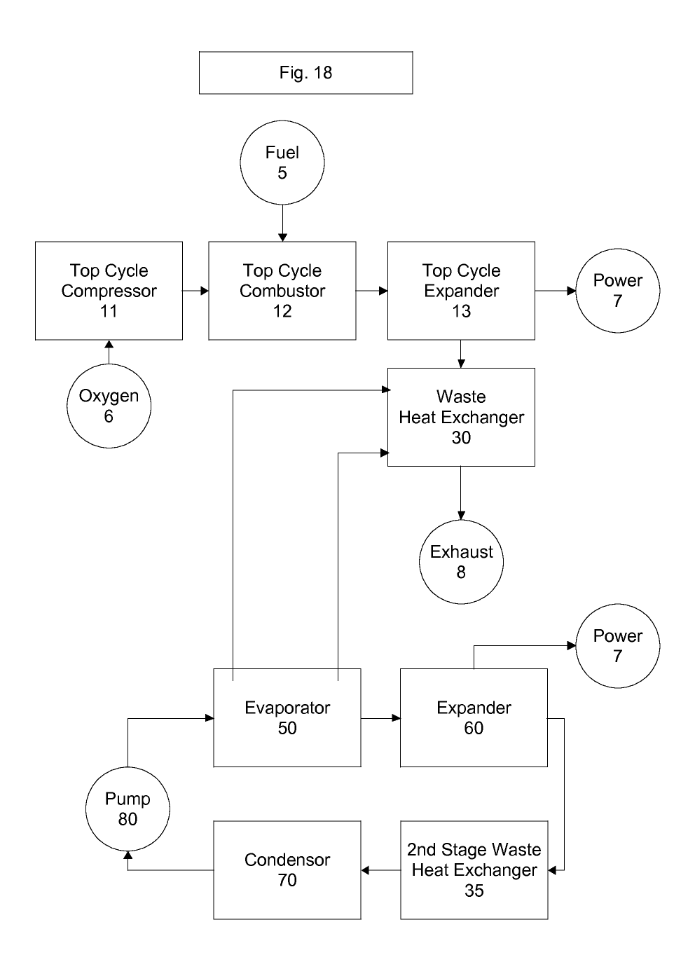

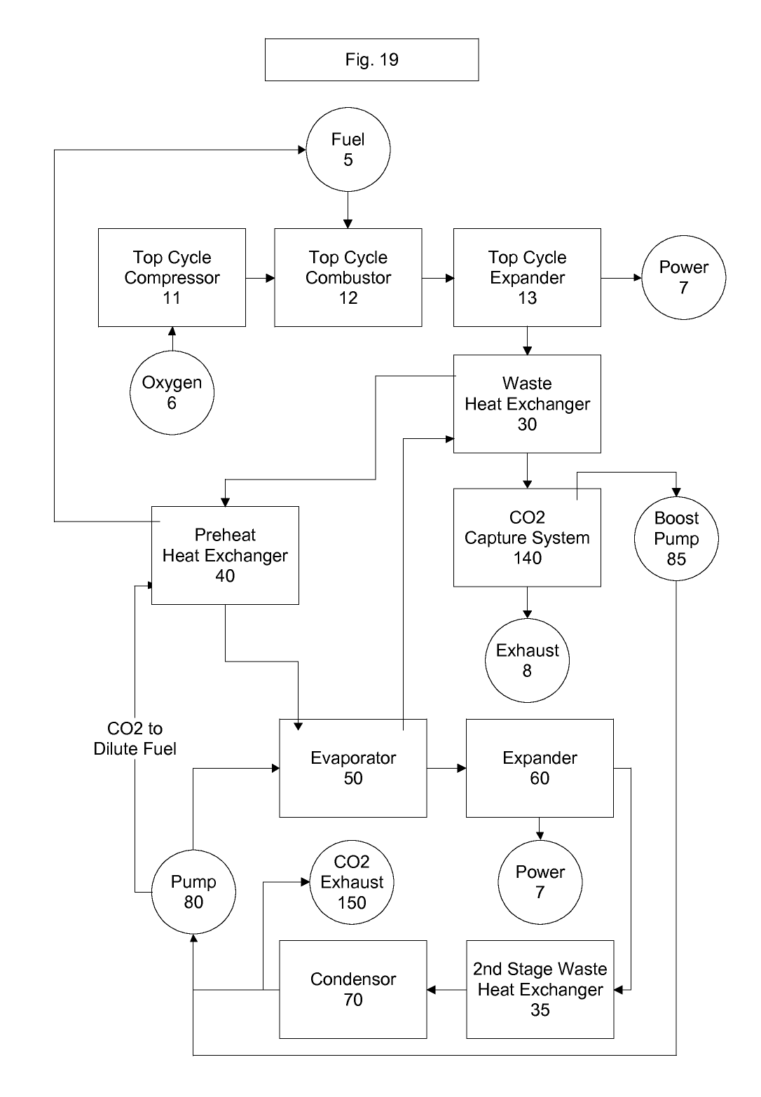

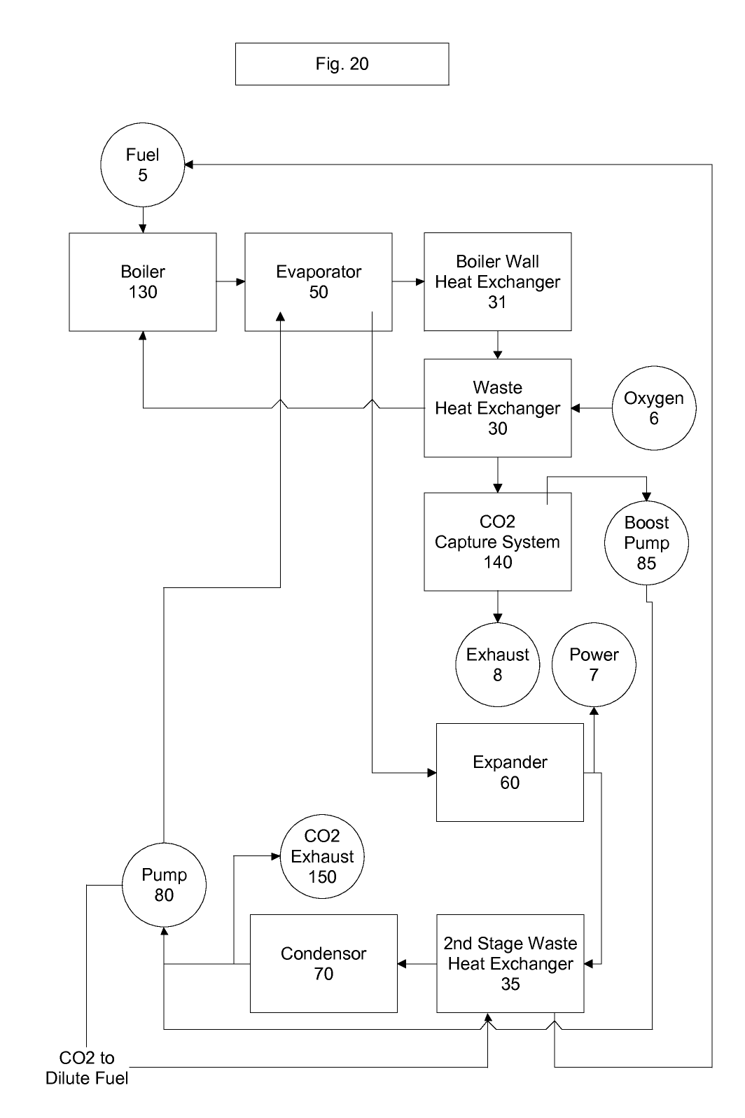

Turning to FIG. 18, FIG. 18 is a sequential flow diagram of another embodiment of a high temperature top cycle power generator that is consisting of top cycle compressor 11, combustor 12, and expander 13, similar to FIG. 16. It is understood that preheating of oxidant, and/or fuel as depicted in other figures can be a feature in this embodiment. In this embodiment combustion air is enriched oxygen 6 (or preferably enriched oxygen, or specifically preferred oxygen above 90% on a weight basis) as a method to reduce the mass flow rate of combustion exhaust per unit of power produced. This is vital to the disclosed invention as the top cycle has a very high discharge temperature upstream of the supercritical CO2 bottom cycle power generation evaporator 50 and/or waste heat exchanger 30. As noted earlier, the combination of high pressure and high temperature (respectively above 2700 psi and 1000 degrees Celsius) requires expensive materials for heat exchangers relative to stainless steel. Additionally, the utilization of enriched oxygen as the oxidant significantly improves combustion flame stability within the ramjet configuration of the adjoining top cycle compressor 11, combustor 12, and expander 13. The particularly preferred embodiment is a compression ratio such that the oxygen discharge temperature from the compressor 11 is above the autoignition point of the fuel prior to mixing within the combustor 12. The supercritical CO2 bottom cycle power generator that is consisting of evaporator 50, then expander 60 (to generator power 7), then an optional 2nd stage waste heat exchanger 35 (or a recuperator as known in the art), then a condenser 70, and finally a pump 80 (or turbocompressor when the low side working fluid remains a vapor) operates as known in the art.

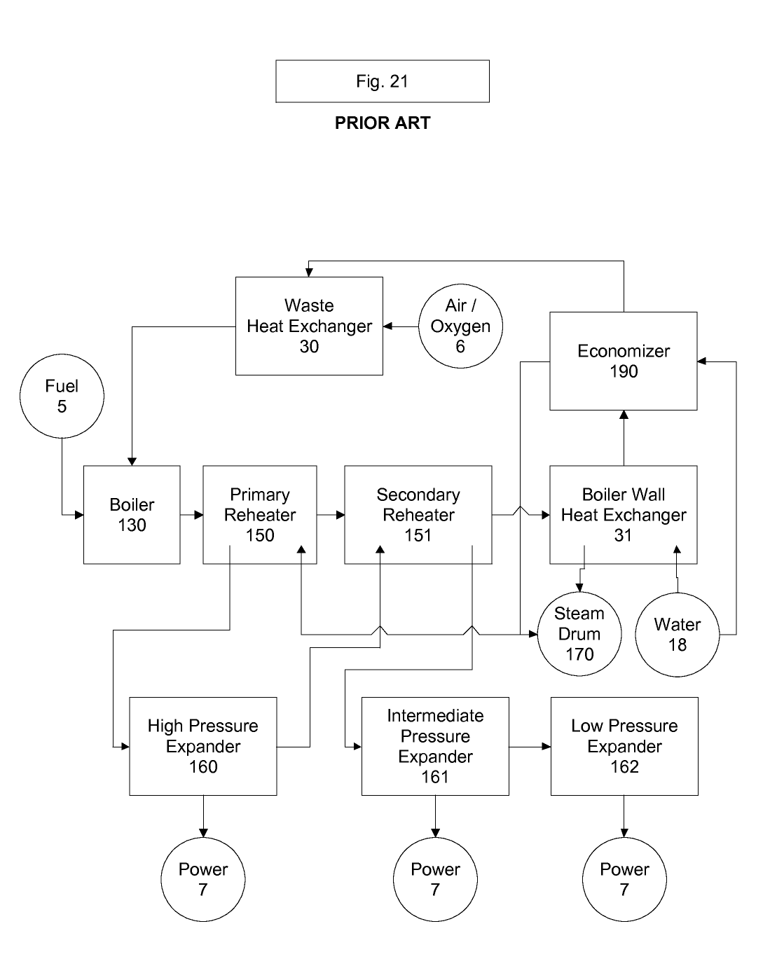

Turning to FIG. 19, FIG. 19 is a sequential flow diagram of another embodiment of a high temperature top cycle power generator that is consisting of top cycle compressor 11, combustor 12, and expander 13, similar to FIG. 16. It is understood that preheating of oxidant, and/or fuel as depicted in other figures can be a feature in this embodiment. In this embodiment combustion air is enriched oxygen 6 (or preferably enriched oxygen, or specifically preferred oxygen above 90% on a weight basis) as a method to reduce the mass flow rate of combustion exhaust per unit of power produced. This is vital to the disclosed invention as the top cycle has a very high discharge temperature upstream of the supercritical CO2 bottom cycle power generation evaporator 50 and/or waste heat exchanger 30. Again, the utilization of enriched oxygen as the oxidant significantly improves combustion flame stability within the ramjet configuration of the adjoining top cycle compressor 11, combustor 12, and expander 13. The particularly preferred embodiment is a compression ratio such that the oxygen discharge temperature from the compressor 11 is above the autoignition point of the fuel prior to mixing within the combustor 12. The supercritical CO2 bottom cycle power generator that is consisting of evaporator 50, then expander 60 (to generator power 7), then an optional 2nd stage waste heat exchanger 35 (or a recuperator as known in the art), then a condenser 70, and finally a pump 80 (or turbocompressor when the low side working fluid remains a vapor) operates as known in the art. However, a vital distinction of this invention is the utilization of a partial stream of high pressure CO2 that is extracted downstream of the pump 80 (or turbocompressor, or if a multistage pump/compressor extracted at the state point closest to the pressure setpoint at the state point upstream of the top cycle combustor 12. This partial stream of high pressure CO2 is utilized to dilute and/or preheat fuel 5 that is to be utilized within the top cycle combustor 12. The preferred embodiment is the additional preheating of the fuel 5 by preheating the CO2 from the partial stream through the preheat heat exchanger 40 by waste heat from the top cycle combustion exhaust prior to entering the top cycle combustor 12. An additional vital aspect of this invention is inclusion of a CO2 capture system 140 that recovers and then isolates at least 1% (preferably greater than 5%, and specifically preferred greater than 90% of the combustion CO2 byproduct). The then isolated CO2, is preferably recovered by utilizing the reversibility of the CO2 capture system chemical reaction, adsorption, or absorption as a method of discharging CO2 (preferably pure, or at least 90% CO2) through the boost pump 85 with minimal energy consumption. The boost pump 85 discharges the isolated CO2 at the low side pressure of the supercritical CO2 bottom cycle upstream of the pump 80. A significant advantage of this operation is the relaxation of CO2 leak requirements for seals within the expander 60 and/or pump 80. This is particularly important in smaller scale systems due in part to lack of commercially available dry seals for small diameter shafts, and in large scale systems due to windage losses of pump 80 motor and/or expander 60 generator. The particularly preferred embodiment has the CO2 leaked being used for a secondary process, such as greenhouse, beverage carbonation, or sequestration through either the CO2 capture system 140 or a second CO2 capture system though not depicted. An additional feature of the invention is the ability to discharge excess CO2 150 from the bottom cycle to adapt to changing conditions on high side and/or low side pressure of the CO2 bottom cycle power generation, due to the continuous availability of CO2 from the top cycle combustion exhaust as discharged through the CO2 capture system 140 and boosted by boost pump 85. As depicted in additional figures as well, the combustion waste heat from the top cycle is utilized for both the preheating of the fuel for top cycle and thermal source for bottom cycle evaporator 50 (either directly or through waste heat exchanger 30). An optional 2nd stage waste heat exchanger 35 is utilized to provide thermal source to secondary thermal or power generation processes.

Turning to FIG. 20, FIG. 20 is a sequential flow diagram of another embodiment of a high temperature power generator top cycle that is consisting of a supercritical (either Brayton or Rankine) CO2 working fluid such that the boiler is a high radiant and emissivity boiler. This embodiment is ideally suited for the retrofit of an existing low efficiency coal fired power plant by leveraging many of the existing components including boiler wall heat exchanger 31. The boiler is high radiant and emissivity by preheating of the oxidant 6 (preferably an enriched oxygen source of greater than 90%) by excess waste heat of the boiler combustion exhaust through waste heat exchanger 30 prior to entering the boiler 130. The fuel 5 is diluted as in FIG. 19 by a slipstream of CO2 discharged from the pump 80 then preheated through the 2nd stage waste heat exchanger 35 and then mixed immediately upstream of the boiler 130 to create at least 10 ppm (and preferably up to 500 ppm) as a method of maximizing boiler combustion emissivity. The evaporator 50, which is preferably comprised of a microchannel heat exchanger has a series of non-imaging optics shape microchannel “tubes” to minimize surface emissivity and to maximize heat transfer into the supercritical CO2. A vital aspect of this invention is the evaporator comprised of these microchannel heat exchangers having an effective surface emissivity of less than 10% (and preferably less than 5%, and specifically preferred of less than 2%) to minimize size of the boiler 130 and evaporator 50 to match the high radiant combustion of greater than 200 kW per square meter (and preferably greater than 350 kW per square meter, and particularly preferred to be greater than 500 kW per square meter). The boiler 130 in a typical coal fired scenario has tubes that line the wall of the heat exchanger to both create saturated steam and maintain the temperature of the boiler wall. In this invention, the boiler 130 has the superheat sections of a typical coal boiler substituted with an evaporator 50 of a supercritical CO2 power generation cycle. The combustion exhaust then passes through to either saturate or superheat the steam downstream of the boiler wall heat exchanger 31, or in the event that supercritical CO2 is also passed through the boiler wall heat exchanger 31 then the combustion exhaust continues to heat the CO2 working fluid. Subsequently, the combustion waste heat is at least partially captured by the waste heat exchanger 30 to preheat the combustion air oxidant 6 (which is preferably an enriched oxygen source) preferably above the autoignition temperature of the fuel 5 prior to being injected into the boiler 130. The preferred embodiment has at least a partial slipstream of the combustion exhaust to capture CO2 in the CO2 capture system 140. A portion of the CO2 reacted through a carbonation reaction, adsorbed or absorbed in the CO2 capture system 140 is isolated (preferably using waste heat from the boiler) and then increased in pressure through the boost pump 85 for injection into the supercritical CO2 power generation system upstream of the pump 80. The availability of CO2 from the CO2 capture system reduces the complexity of the CO2 working fluid inventory management system, and as noted earlier reduces the cost and complexity of seals around the moving parts of the CO2 power generation system being the expander 60 and pump 80 (or turbocompressor when Brayton cycle). At least a portion of the bottom cycle waste heat, as extracted from the 2nd stage waste heat exchanger 35 is utilized to preheat high pressure CO2 downstream of the pump 80 that then dilutes and preheats the fuel 5 (preferably above the autoignition temperature of the fuel 5). And as noted earlier in FIG. 19, the supercritical CO2 power generation system has the ability to discharge CO2 exhaust 150 as a simplified method of working fluid inventory control. The condenser 70 and expander 60 operate as depicted in earlier figures.

Turning to FIG. 21, FIG. 21 is a prior art embodiment of a typical coal power plant. Fuel 5, which is coal, is injected into the boiler 130 at various injection points so as to achieve a combustion fireball with the desired heat transfer and emissions controls. The combustion exhaust first heats the primary reheater 150, then the secondary reheater 151, then in part the boiler wall heat exchanger 31. The combustion exhaust then goes through the economizer 190 and finally through the waste heat exchanger 30 that serves to preheat the combustion air 6. Steam that passes through the boiler wall heat exchanger 31 ultimately ends up in the steam drum 170, which is then subsequently superheated by the primary reheater 150, passes through the high pressure expander 160 (which generates power 7) is then reheated through the secondary reheater 151 prior to going through the intermediate pressure expander 161 (which generates power 7) and finally passes through the low pressure expander 162 (which also generates power 7).

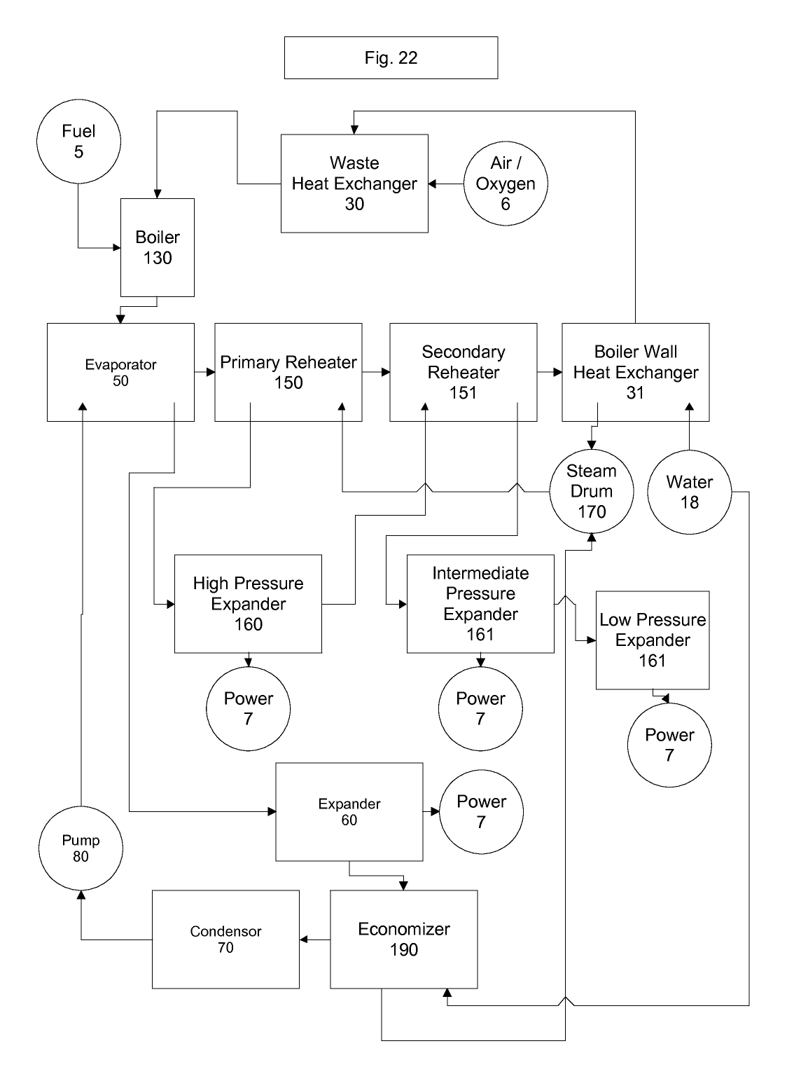

Turning to FIG. 22, FIG. 22 is an embodiment of a retrofitted typical coal power plant. Fuel 5, which is coal, is injected into the boiler 130 at various injection points so as to achieve a combustion fireball with the desired heat transfer and emissions controls. The combustion exhaust first heats the evaporator 50 of the supercritical CO2 power generation cycle, and then to the primary reheater 150, then the secondary reheater 151, then in part the boiler wall heat exchanger 31. In this embodiment, the combustion exhaust does not pass through an economizer at this point but rather just finally through the waste heat exchanger 30 that serves to preheat the combustion air 6. Steam that passes through the boiler wall heat exchanger 31 ultimately ends up in the steam drum 170, which is then subsequently superheated by the primary reheater 150, passes through the high pressure expander 160 (which generates power 7) is then reheated through the secondary reheater 151 prior to going through the intermediate pressure expander 161 (which generates power 7) and finally passes through the low pressure expander 162 (which also generates power 7). Water 18, which was condensed through the steam generation power cycle condenser (not depicted as known in the art) passes through both the boiler wall heat exchanger 31 and separately through the economize 190 (which in this embodiment is downstream of the supercritical CO2 power generation system's expander 60 (which also generates power 7). The CO2 working fluid then passes through the condenser 70 prior to being pumped to the high side pressure and starting the cycle again. It is understood that the CO2 cycle can optionally have a recuperator as known in the art. Though not depicted, it is understood that a CO2 capture system as noted in earlier figures can be included in this embodiment.

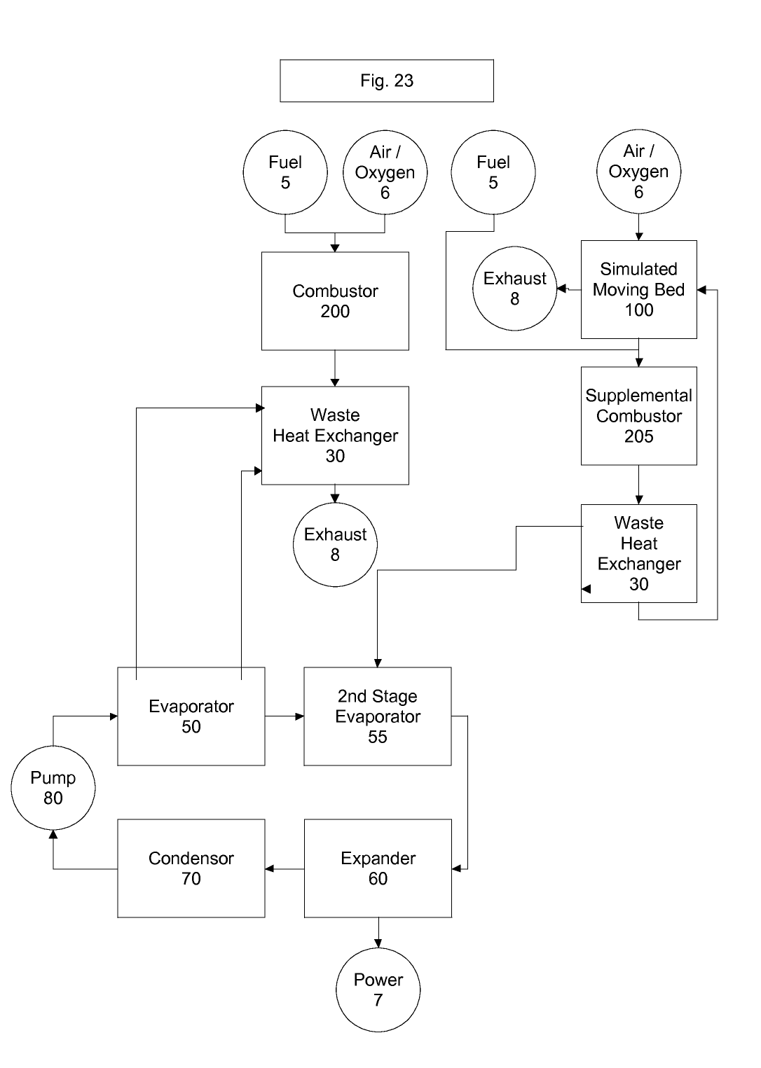

Turning to FIG. 23, FIG. 23 is an embodiment of the invention where thermal energy is recovered from a combustor 200 that produces combustion exhaust 8 from the combustion of fuel 5 and oxidant source 6. The key feature of the invention in this embodiment is the ability to increase the temperature of a bottom cycle power generation system such as the depicted supercritical CO2 power generation system beyond the waste heat temperature recovered from the combustor 200 through the waste heat exchanger 30 and transferred to the evaporator 50 (or preferably by physical placement of the evaporator in place of the waste heat exchanger 30 in an energy efficient manner. This is accomplished using a supplemental combustor 205 that combusts fuel 5 (which can also be preheated and diluted as depicted in earlier figures) configured with a simulated moving bed 100. The simulated moving bed 100 captures thermal energy from the supplemental combustor 205 as a method to preheat its oxidant source 6. The thermal energy from the supplemental combustor 205 is utilized as the 2nd stage evaporator 55, which effectively superheats the CO2 working fluid downstream of the first evaporator 50. The expander 60, which generates power 7, the condenser 70, and pump 80 operate in an identical manner as earlier figures.

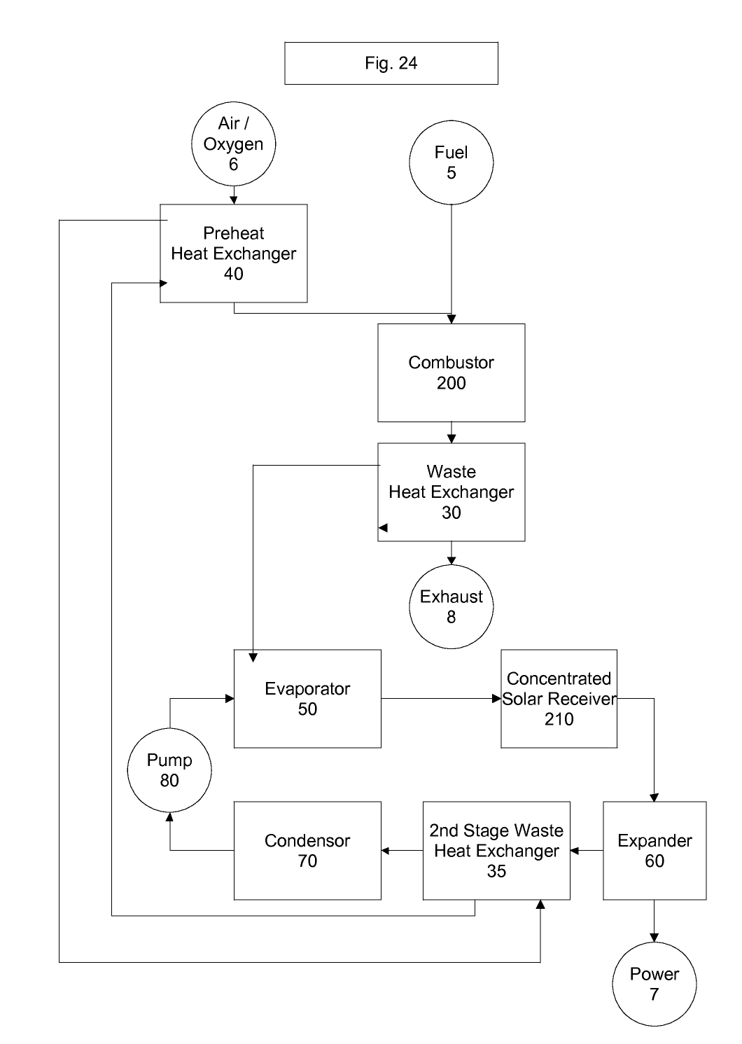

Turning to FIG. 24, FIG. 24 is an embodiment of the invention where thermal energy is recovered from a combustor 200 that produces combustion exhaust 8 from the combustion of fuel 5 and oxidant source 6. The key feature of the invention in this embodiment is the ability to increase the temperature of a bottom cycle power generation system such as the depicted supercritical CO2 power generation system beyond the waste heat temperature recovered from the combustor 200 through the waste heat exchanger 30 and transferred to the evaporator 50 (or preferably by physical placement of the evaporator in place of the waste heat exchanger 30 in an energy efficient manner. This is accomplished using a concentrated solar receiver 210 that has the distinct advantage of no combustion byproducts. The simulated moving bed as noted in the prior FIG. 23, though not depicted, can be utilized in series with and upstream of the concentrated solar receiver 210. The thermal energy from the concentrated solar receiver 210 is utilized as the 2nd stage evaporator that effectively superheats the CO2 working fluid downstream of the first evaporator 50. The expander 60, which generates power 7, the condenser 70, and pump 80 operate in an identical manner as earlier figures. Waste heat from the supercritical CO2 power generation cycle, as recovered from the 2nd stage waste heat exchanger 35 is utilized to preheat the oxidant source 6 of the combustor 200. It is understood that the 2nd stage waste heat exchanger can simply have physical placement within the air flow of the oxidant source 6.

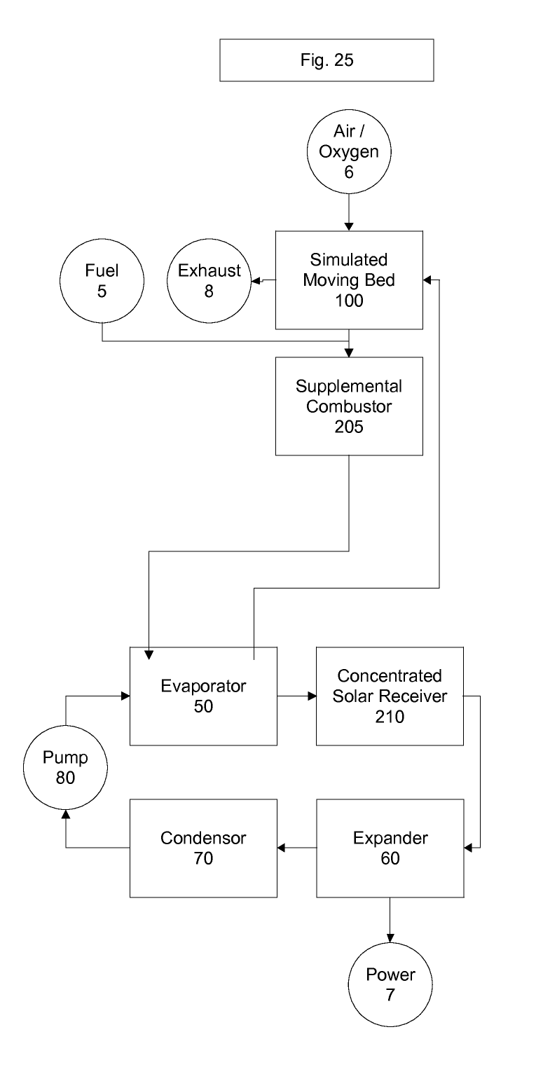

Turning to FIG. 25, FIG. 25 depicts a preferred embodiment for a CO2 power generating cycle that operates as an on-demand power system with nominal additional efficiency losses as compared to a typical gas turbine with heat recovery steam generator, but predominantly designed as a solar thermal power generation system. In order for the power generation system to operate with partial solar load, a simulated moving bed 100 with a supplemental combustor 205 is required. The supplemental combustor 205 produces combustion exhaust that transfer thermal energy into the CO2 power generating cycle through the evaporator 50 immediately downstream of the pump 80 which increases the CO2 working fluid from the low side pressure to the high side pressure. The combustion exhaust then passes through the simulated moving bed 100 as a method to preheat the oxidant source 6. The remaining thermal energy from the exhaust can be utilized, though not depicted, to preheat the fuel 5. It is also understood that the embodiments that depict CO2 capture system as a method to source CO2 to makeup for CO2 leaks within the CO2 power generating cycle, and the use of recuperators or cascaded cycles as known in the art can be part of the depicted CO2 power generating cycle.

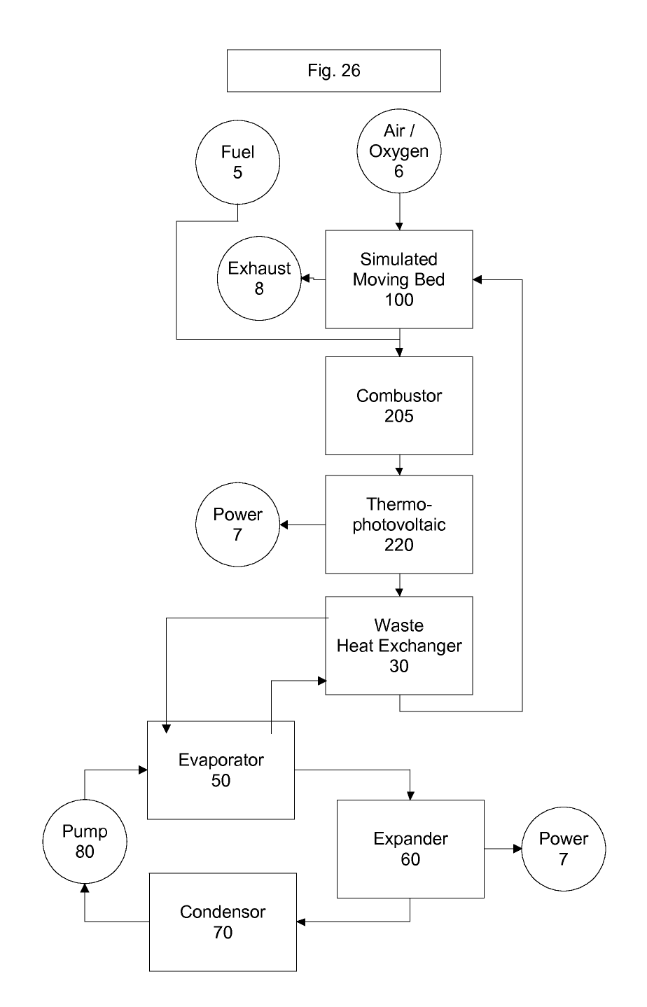

Turning to FIG. 26, FIG. 26 depicts another preferred embodiment for a CO2 power generating cycle that operates as an on-demand power system with nominal additional efficiency losses as compared to a typical gas turbine with heat recovery steam generator, but predominantly designed as a thermophotovoltaic power generation system operating as the top cycle. In order for the power generation system to operate with high efficiency, a simulated moving bed 100 with a combustor 205 having high radiant and emissivity is required. The combustor 205 creates an artificial sun for the thermophotovoltaic cells (preferably at a temperature great than 2000 degrees Kelvin, particularly preferred greater than 3000 degrees Kelvin, and specifically greater than 3200 degrees Kelvin) so that the radiative emission spectrum is optimized for the thermophotovoltaic cells (which are hybrid multijunction photovoltaic cells) power 7 production. The combustor 205 produces combustion exhaust that transfers thermal energy into the CO2 bottom cycle power generating cycle through the evaporator 50 (or as shown first through the waste heat exchanger 30) immediately downstream of the pump 80 that increases the CO2 working fluid from the low side pressure to the high side pressure, and then passes through the simulated moving bed 100 as a method to preheat the oxidant source 6. The remaining thermal energy from the exhaust can be utilized, though not depicted, to preheat the fuel 5. It is understood that the oxidant source 6 can range from having the natural weight percent of oxygen in air up to pure oxygen, or the preferred oxygen content of greater than 50% or the specifically preferred oxygen content of greater than 90% on a mass fraction basis. It is also understood that the embodiments that depict CO2 capture system as a method to source CO2 to makeup for CO2 leaks within the CO2 power generating cycle, and the use of recuperators or cascaded cycles as known in the art can be part of the depicted CO2 power generating cycle. The expander 60, which generates power 7, the condenser 70, and pump 80 operate in an identical manner as earlier figures.

It is understood in this invention that a combination of scenarios can be assembled through the use of waste heat exchangers, simulated moving bed heat recovery systems, and fluid valves such that any of the alternate configurations can be in parallel enabling the top cycle power generator to support a wide range of secondary bottom processes or cycles.

Although the invention has been described in detail with particular reference to certain embodiments detailed herein, other embodiments can achieve the same results. Variations and modifications of the present invention will be obvious to those skilled in the art and the present invention is intended to cover in the appended claims all such modifications and equivalents.

What is claimed is:

1. An energy production system operable to reduce fuel requirement of a combined thermodynamic power generating top cycle comprising: a) a first thermodynamic power generating cycle having a first combustion stage and a first working fluid and producing a first stage of combustion exhaust yielding a first waste heat byproduct, wherein the first thermodynamic power generating cycle consumes fuel to generate power; and b) a second combustion stage consuming the first stage of combustion exhaust and additional oxidant producing a second stage of combustion exhaust having a radiant flux greater than 100 kW per square meter and emissivity greater than 0.2.

2. The energy production system according to claim 1 wherein the first combustion stage has a fuel source and an oxidant source whereby the first combustion stage has at least a 1.0 percent stoichiometric excess of fuel.

3. The energy production system according to claim 2 wherein the stoichiometric excess of fuel is operable to reduce the production of NOx.

4. The energy production system according to claim 2 wherein the stoichiometric excess of fuel is operable to product soot and/or soot precursors for the second stage of combustion operable to increase by at least 10 percent the emissivity of the second stage of combustion exhaust.

5. The energy production system according to claim 1 wherein the radiant flux is greater than 300 kW per square meter and emissivity is greater than 0.5.

6. The energy production system according to claim 1 wherein the radiant flux is greater than 500 kW per square meter and emissivity is greater than 0.8.

7. The energy production system according to claim 1 wherein the radiant flux is greater than 500 kW per square meter and emissivity is greater than 0.9.

8. The energy production system according to claim 1 wherein the first thermodynamic power generating cycle is comprised of a ramjet.

9. The energy production system according to claim 8 wherein the additional oxidant is at least in part preheated by either the first stage of combustion exhaust or the second stage of combustion exhaust.

10. The energy production system according to claim 9 wherein the additional oxidant is comprised of at least 30 percent oxygen.

11. The energy production system according to claim 10 wherein the additional oxidant is injected into the second stage combustion exhaust operable to capture enthalpy from the second stage combustion exhaust.

12. The energy production system according to claim 2 wherein the second stage combustion exhaust is utilized to preheat at least one of the fuel source or the oxidant source for the first combustion stage, or a fuel source or the oxidant source for the second combustion stage.

13. An energy production system operable to reduce fuel requirement of a combined thermodynamic power generating top cycle comprising: a) a first thermodynamic power generating cycle having a first expander device and a first combustion stage and a first working fluid and producing a first stage of combustion exhaust having a pressure greater than 100 psi and yielding a first waste heat byproduct comprised of at least carbon dioxide and water vapor, wherein the first thermodynamic power generating cycle consumes fuel to generate power; b) a second thermodynamic power generating cycle having a second working fluid and a second expander device with an inlet pressure of greater than the second working fluid supercritical pressure, and a heat exchanger to recover thermal energy from the first stage of combustion exhaust; c) a third expander device operable to produce power wherein the third expander device is downstream of the heat exchanger having a state point inlet pressure and inlet temperature at which the first waste heat byproduct water vapor is condensed.

14. The energy production system according to claim 13 wherein the first thermodynamic power generating top cycle is a ramjet.

15. The energy production system according to claim 14 wherein the second thermodynamic power generating second expander device is a ramjet expander.

16. The energy production system according to claim 15 wherein the second thermodynamic power generating cycle is a Brayton cycle and has a ramjet compressor.

17. The energy production system according to claim 15 wherein the second thermodynamic power generating cycle is a Rankine cycle.

18. The energy production system according to claim 13 wherein the second thermodynamic power generating cycle second working fluid is carbon dioxide.

19. The energy production system according to claim 13 wherein the first combustion stage occurs at a pressure at least 5 psi greater than the supercritical pressure of carbon dioxide and a temperature at least 2 degrees Celsius greater than the supercritical temperature of carbon dioxide.

20. The energy production system according to claim 13 wherein the first thermodynamic power generating top cycle first combustion stage combusts a fuel and an oxidant and wherein the fuel and oxidant are preheated to a temperature greater than the autoignition temperature of the fuel.

21. The energy production system according to claim 20 wherein the fuel and oxidant are preheated by at least one of first stage of combustion exhaust or second stage thermodynamic power generating cycle downstream of the second expander device.

22. The energy production system according to claim 13 wherein the second stage thermodynamic power generating cycle has a second working fluid leak mass flow rate and a low side pressure, wherein a mass flow rate of the first working fluid is captured downstream of the condensing of water vapor from the first thermodynamic power generating cycle first stage exhaust at a pressure at least 5 psi greater than the low side pressure of the second stage thermodynamic power generating cycle.

23. The energy production system according to claim 22 wherein the mass flow rate of the first working fluid captured is operable to eliminate the requirement of dry seal or hermetic seal of the second stage thermodynamic power generating cycle.

24. The energy production system according to claim 13 wherein the first stage of combustion exhaust has a pressure greater than 500 psi.

25. The energy production system according to claim 13 wherein the first stage of combustion exhaust has a pressure greater than 1000 psi.

26. The energy production system according to claim 13 wherein the first stage of combustion exhaust has a pressure greater than 1500 psi.

27. The energy production system according to claim 13 wherein the first stage of combustion exhaust has a temperature greater than 500 degrees Celsius.

28. The energy production system according to claim 13 wherein the first stage of combustion exhaust has a temperature greater than 700 degrees Celsius.

29. The energy production system according to claim 13 wherein the first stage of combustion exhaust has a temperature greater than 1000 degrees Celsius.

30. The energy production system according to claim 13 wherein the first stage of combustion exhaust has a temperature greater than 1200 degrees Celsius.

31. The energy production system according to claim 13 wherein the first stage of combustion exhaust has a temperature greater than 1500 degrees Celsius.

32. An energy production system operable to maximize exergy efficiency of a combined thermodynamic power generating top cycle comprising: a) a first thermodynamic power generating cycle having a first combustion stage and a first working fluid and producing a first stage of combustion exhaust yielding a first waste heat byproduct, wherein the first thermodynamic power generating cycle consumes fuel to generate power; and b) a second combustion stage consuming the first stage of combustion exhaust and at least one of additional oxidant or fuel injected downstream of the first stage of combustion and upstream of a second stage of combustion, and at least 5 ppm of soot and/or soot precursors upstream of the second stage of combustion resulting in the second stage of combustion exhaust having a radiant flux greater than 100 kW per square meter and emissivity greater than 0.2.

33. The energy production system according to claim 32 wherein the at least one of additional oxidant or fuel upstream of the second stage of combustion are at a temperature greater than at least 5 degrees Celsius above the fuel's autoignition temperature.

34. The energy production system according to claim 32 wherein the fuel consumed by the first thermodynamic power generating cycle is at a stoichiometric excess yielding at least 5 ppm of soot and/or soot precursors upstream of the second stage of combustion stage.

35. The energy production system according to claim 32 further comprised of a soot and/or soot precursors generator, wherein at least 5 ppm of soot and/or soot precursors is injected upstream of the second stage of combustion stage.

36. The energy production system according to claim 32 wherein additional fuel at a stochiometric excess of any uncombusted oxidant is injected into the first combustion stage exhaust, and then additional preheated oxidant is injected at a temperature above the fuel's autoignition temperature.

37. The energy production system according to claim 32 wherein the second stage of combustion exhaust has a radiant flux greater than 300 kW per square meter and emissivity greater than 0.5.

38. The energy production system according to claim 32 wherein the second stage of combustion exhaust has a radiant flux greater than 500 kW per square meter and emissivity greater than 0.8.

39. The energy production system according to claim 32 wherein the second stage of combustion exhaust has a radiant flux greater than 500 kW per square meter and emissivity greater than 0.9

40. The energy production system according to claim 32 wherein the second stage of combustion exhaust is combusted within an industrial furnace including furnaces of steel, aluminum, silicon, and glass.

41. The energy production system according to claim 32 wherein the second stage of combustion exhaust is combusted within an industrial kiln including ceramic, and cement.

42. The energy production system according to claim 32 wherein the first thermodynamic power generating top cycle is comprised of a sequential set of components in order of a top cycle compressor, a top cycle external preheat, a top cycle combustor, and a top cycle expander wherein the top cycle external preheat captures waste heat from the second stage of combustion exhaust.

43. The energy production system according to claim 32 wherein the top cycle external preheat captures waste heat first from the second stage of combustion exhaust and then subsequently from a concentrated solar light source.

44. The energy production system according to claim 42 wherein the second stage of combustion exhaust is subsequently captured by a third thermodynamic power generating cycle.

45. An energy production system operable to maximize exergy efficiency of a combined thermodynamic power generating top cycle comprising: a) a first thermodynamic power generating cycle having a first combustion stage and a first working fluid and producing a first stage of combustion exhaust yielding a first waste heat byproduct, wherein the first thermodynamic power generating cycle consumes fuel to generate power; and b) a second combustion stage consuming the first stage of combustion exhaust and at least one of additional oxidant or fuel injected downstream of the first stage of combustion and upstream of a second stage of combustion, and at least 5 ppm of soot and/or soot precursors upstream of the second stage of combustion resulting in the second stage of combustion exhaust having a radiant flux greater than 100 kW per square meter and emissivity greater than 0.2.

46. The energy production system according to claim 45 wherein the at least 5 ppm of soot and/or soot precursors upstream of the second stage of combustion is created by the incomplete combustion of the fuel within the first combustion stage of the first thermodynamic power generating cycle.

47. The energy production system according to claim 45 wherein the additional oxidant is monoatomic oxygen.

48. The energy production system according to claim 45 wherein the first thermodynamic power generating cycle is consisting of a ramjet expander.

49. The energy production system according to claim 45 wherein the first thermodynamic power generating cycle is consisting of a ramjet compressor.

50. The energy production system according to claim 48 wherein the ramjet expander is an inside-out ramjet expander.

51. The energy production system according to claim 49 wherein the ramjet compressor is an inside-out ramjet compressor.

52. An energy production system operable to maximize exergy efficiency of a combined thermodynamic power generating top cycle comprising: a) a first thermodynamic power generating cycle having a first combustion stage, a ramjet expander and a first working fluid and producing a first stage of combustion exhaust having a temperature greater than 1000 degrees Celsius and an emissivity less than 0.50, yielding a first waste heat byproduct, wherein the first thermodynamic power generating cycle consumes fuel to generate power; and b) a second combustion stage consuming the first stage of combustion exhaust and at least one of additional oxidant or fuel injected downstream wherein the mixing of the additional oxidant or fuel occurs following at least one of the additional oxidant or fuel preheated to above the fuel autoignition temperature resulting in the second stage of combustion exhaust having a radiant flux greater than 100 kW per square meter and emissivity greater than 0.2.

53. The energy production system according to claim 52 wherein a thermophotovoltaic cell that consists of a multijunction photovoltaic cell having an average quantum energy conversion efficiency of greater than 80 percent for the multijunction photovoltaic cell operable spectrum range.

54. An energy production system operable to maximize exergy efficiency of a combined thermodynamic power generating top cycle comprising: a) a first thermodynamic power generating cycle having a first combustion stage and a first working fluid and producing a first stage of combustion exhaust having a temperature greater than 1000 degrees Celsius and an emissivity less than 0.20, yielding a first waste heat byproduct, wherein the first thermodynamic power generating cycle consumes fuel to generate power; b) a second combustion stage consuming the first stage of combustion exhaust and at least one of additional oxidant or fuel injected downstream wherein the mixing of the additional oxidant or fuel occurs following at least one of the additional oxidant or fuel preheated to above the fuel autoignition temperature resulting in the second stage of combustion exhaust having a radiant flux greater than 100 kW per square meter and emissivity greater than 0.2; and c) a simulated moving bed operable to recover combustion waste heat to preheat at least one of oxidant source or fuel.

55. The energy production system according to claim 54 is further comprised of a second thermodynamic power generating cycle void of a combustor, wherein the waste heat not recovered by the simulated moving bed is operable to evaporate supercritical CO2 within the second thermodynamic power generating cycle void of a combustor.

56. The energy production system according to claim 55 is consisting of a first thermodynamic power generating cycle compressor and combustor, wherein waste heat from the second thermodynamic power generating cycle is operable to preheat combustion air of the first thermodynamic power generating cycle downstream of the first thermodynamic power generating cycle compressor and upstream of the first thermodynamic power generating cycle combustor.

57. The energy production system according to claim 54 is consisting of a first thermodynamic power generating cycle expander wherein the simulated moving bed is downstream of the first thermodynamic power generating cycle expander.

58. The energy production system according to claim 54 wherein the simulated moving bed is downstream of the second combustion stage.

59. An energy production system comprising a top cycle furnace having a high radiant flux of greater than 200 kW per square meter and an emissivity of greater than 0.50 through the combustion of at least one preheated oxidant source or fuel; and a first simulated moving bed operable as the top cycle furnace waste heat recovery system wherein the top cycle furnace has combustion exhaust above the fuels autoignition temperature, wherein at least a partial stream of the combustion exhaust entrains at least a portion of the fuel operable to preheat the fuel and to create at least 5 ppm of soot or soot precursors upstream of the top cycle furnace.

60. The energy production system according to claim 59 further comprised of a second simulated moving bed operable to preheat the oxidant source wherein the oxidant source has an oxygen mass fraction of greater than 40 percent up to 100 percent, and wherein the first simulated moving bed is operable to preheat the fuel source.

61. The energy production system according to claim 59 further comprised of a second simulated moving bed wherein the simulated moving bed is consisting of a chemical medium that has an exothermic carbonation reaction with reactant including CO2 from the combustion exhaust.

62. An energy production system operable to maximize exergy efficiency of a combined power generating cycle comprising: a) a furnace having a combustion stage to combust a preheated oxidant and both a diluted and preheated fuel with a temperature greater than 1000 degrees Celsius and an emissivity greater than 0.50, yielding a combustion exhaust having a waste heat byproduct; and b) a first thermodynamic supercritical power generating cycle consisting of an expander having a CO2 as the working fluid that is heated by the furnace combustion exhaust and heat exchanger downstream of the expander to transfer thermal energy to preheat the furnace oxidant above the fuels ignition temperature and then a partial stream of the combustion exhaust dilutes and preheats the fuel above the fuels autoignition temperature.

63. An energy production system operable to maximize exergy efficiency of a combined thermodynamic power generating top cycle comprising: a) a first thermodynamic power generating cycle having a compressor to compress an oxidant source that is then preheated by thermal energy transferred by a first simulated moving bed having a medium that reacts with carbon dioxide to create an exothermic reaction, a first combustion stage and a first working fluid and producing a first stage of combustion exhaust having a temperature greater than 1000 degrees Celsius and an emissivity less than 0.20, yielding a first waste heat byproduct that is discharged into a second simulated moving bed that preheats an oxidant for a boiler that heats a second thermodynamic power generating cycle having a supercritical CO2 working fluid, wherein the boiler has a radiant flux greater than 100 kW per square meter and an emissivity greater than 0.20.

64. The energy production system according to claim 63 wherein the boiler combusts a fuel and the preheated oxidant having an inlet temperature greater than the fuels autoignition temperature.

65. The energy production system according to claim 63 further comprised of a second stage evaporator downstream of the second simulated moving bed operable to transfer heat into a third thermodynamic power generating cycle.

66. An energy production system comprised of a first thermodynamic power generating system having a combustor operable as an oxyfuel ramjet expander operable as a Brayton cycle having a discharge temperature downstream of the ramjet expander greater than 1000 degrees Celsius that is a thermal source for a second thermodynamic power generating system having a supercritical CO2 working fluid operable at a pressure greater than 2700 psi through a waste heat exchanger having a physical size less than 75% of a waste heat exchanger for an equivalent steam working fluid.

67. The energy production system according to claim 66 wherein the waste heat exchanger has a physical size less than 85% of a waste heat exchanger for an equivalent steam working fluid.

68. The energy production system according to claim 66 consisting of an oxidant source having an oxygen weight mass fraction greater than 40% wherein the waste heat from the second thermodynamic power generating system is utilized to preheat the oxidant source.

69. An energy production system comprised of a first thermodynamic power generating system operable as an open Brayton cycle with a combustor burning a fuel that is diluted with a preheated CO2 and consisting of a waste heat exchanger and a CO2 capture system with a boost pump operable as at least a partial CO2 source; a second thermodynamic power generating system having a supercritical CO2 working fluid and a CO2 exhaust port operable to regulate the mass of CO2 within the second thermodynamic power generating system and a pump or compressor to provide pressurized CO2 to the first thermodynamic power generating system operable to dilute the fuel source, wherein the waste heat exchanger transfers waste heat from the first thermodynamic power generating system to the second thermodynamic power generating system, and wherein the preheated CO2 is discharged from downstream of the pump or compressor of the second thermodynamic power generating system.

70. The energy production system according to claim 69 wherein the at least partial CO2 source is injected upstream of the second thermodynamic power generating system pump operable to add CO2 working fluid within the second thermodynamic power generating system to achieve a high-side and low-side pressure of the second thermodynamic power generating system in equilibrium with CO2 discharged to dilute the fuel source and CO2 leaked through a expander of the second thermodynamic power generating system.

71. The energy production system according to claim 69 further comprised of a second waste heat exchanger to transfer waste heat from the second thermodynamic power generating system to the first thermodynamic power generating system.

72. An energy production system operable to maximize exergy efficiency of a combined first thermodynamic power generating cycle having a supercritical CO2 working fluid; a boiler having a boiler wall heat exchanger and a combustion stage at a temperature greater than 1000 degrees Celsius, an emissivity greater than 0.50, and a heat transfer rate to the supercritical CO2 working fluid of greater than 200 kW per square meter; the boiler combustion stage combusts an oxidant and a fuel source having at least one of the oxidant or fuel preheated by waste heat from the first thermodynamic power generating cycle; and a second thermodynamic power generating cycle having at least 20 percent of a thermal energy source from the boiler wall heat exchanger.

73. The energy production system according to claim 72 further comprised of a thermophotovoltaic cell solid state energy conversion device operable to capture at least 5 percent of the radiant energy, whereby the thermophotovoltaic cell is on the interior facing boiler wall heat exchanger.

74. The energy production system according to claim 72 further comprised of a CO2 capture system with a boost pump operable as at least a partial CO2 source to the first thermodynamic power generating cycle, and a CO2 exhaust port operable to regulate the mass of CO2 within the first thermodynamic power generating system.

75. The energy production system according to claim 72 wherein the fuel is natural gas, syngas, or volatilized organic chemicals from coal and the fuel is preheated by waste heat from either the first or second thermodynamic power generating system.

76. The energy production system according to claim 72 wherein the second thermodynamic power generating system is a steam cycle having at least two of the three high pressure, intermediate pressure and low pressure expander; and the second thermodynamic power generating system has an economizer having its thermal source at least in part from waste heat recovered and downstream of the first thermodynamic power generating system expander.

77. The energy production system according to claim 73 further comprised of a fuel having an autoignition temperature and an oxidant source for the boiler combustion stage; and simulated moving bed operable to recover waste heat downstream of the thermophotovoltaic cell wherein the waste heat is utilized to preheat the oxidant source for the boiler combustion stage to a temperature above the fuels autoignition temperature.

78. An energy production system operable to maximize exergy efficiency of a thermodynamic power generating cycle comprising: a) a first thermal source from a first combustor having waste heat; b) a second thermal source from a second combustor wherein the second thermal source has a temperature at least 200 degrees Celsius greater than the first thermal source; c) a simulated moving bed to recover waste heat from the second thermal source operable to preheat an oxidant source for the second combustor; d) a first thermodynamic power generating cycle having a supercritical CO2 working fluid heated first by the first thermal source and then by the second thermal source.

79. The energy production system according to claim 78 further comprised of a thermophotovoltaic cell solid state power generator within the second combustor having a radiant flux of greater than 200 kW per square meter and emissivity greater than 0.50.

80. The energy production system according to claim 78 wherein the thermodynamic power generating cycle is consisting of at least one cascaded cycle and is void of a recuperator.

81. An energy production system operable to maximize exergy efficiency of a thermodynamic power generating cycle comprising: a) a first thermal source from a first combustor having waste heat; b) a second thermal source from a concentrated solar receiver wherein the second thermal source has a temperature at least 200 degrees Celsius greater than the first thermal source; c) a first thermodynamic power generating cycle having a supercritical CO2 working fluid heated first by the first thermal source and then by the second thermal source, and an expander operable to produce mechanical or electrical power; and d) waste heat from the first thermodynamic power generating cycle utilized to preheat an oxidant source for the first combustor.

82. The energy production system according to claim 81 having a CO2 working fluid maximum operating temperature, a fuel mass flow regulator, and a CO2 working fluid temperature downstream of the first thermal source operable to limit the CO2 working fluid temperature discharge temperature discharged from the concentrated solar receiver and upstream of the expander less than the CO2 maximum operating temperature.

83. The energy production system according to claim 81 further comprised of a simulated moving bed operable as a waste heat recovery system for the first combustor wherein the waste heat recovered from the simulated moving bed is operable to preheat an oxidant source for the first combustor.

84. A method for operating an energy production system having a combined thermodynamic power generating top cycle, a first thermodynamic power generating cycle having a first combustion stage and a first working fluid and producing a first stage of combustion exhaust yielding a first waste heat byproduct, wherein the first thermodynamic power generating cycle consumes fuel to generate power; and b) a furnace having a furnace temperature setpoint whereby the second stage working fluid results from the second combustion stage consuming the first stage of combustion exhaust and additional oxidant producing a second stage of combustion exhaust; comprising the steps of: adding a quantity of fuel and oxidant to the first combustion stage to yield a first stage of combustion exhaust having a first stage exhaust temperature; adding additional oxidant to the second combustion stage to yield a second stage combustion exhaust having a second stage exhaust temperature at least 10 degrees Celsius greater than the furnace temperature setpoint.
